(19) United States
(12) Patent Application Publication
(10) Pub. No.: US 2020/0194651 A1
(43) Pub. Date: Jun. 18, 2020

(54) THERMOELECTRIC CONVERSION UNIT, POWER GENERATION SYSTEM, AND THERMOELECTRIC CONVERSION METHOD

(71) Applicant: NEC CORPORATION, Tokyo (JP)

(72) Inventors: Yuma IWASAKI, Tokyo (JP); Masahiko ISHIDA, Tokyo (JP); Akihiro KIRIHARA, Tokyo (JP); Koichi TERASHIMA, Tokyo (JP); Ryohto SAWADA, Tokyo (JP); Hiroko SOMEYA, Tokyo (JP)

(73) Assignee: NEC CORPORATION, Tokyo (JP)

(21) Appl. No.: 16/467,788

(22) PCT Filed: Dec. 5, 2017
(86) PCT No.: PCT/JP2017/043618

§ 371 Date: Jun. 7, 2019

(30) Foreign Application Priority Data
Dec. 8, 2016 (JP) 2016-238405

(51) Int. Cl. H01L 35/32

(52) U.S. Cl. CPC H01L 35/32

(57) ABSTRACT

A thermoelectric conversion unit includes a plurality of pipes 1 and a thermoelectric conversion element. A first fluid flows through the pipe 1. The thermoelectric conversion element 2 is wound around each of the pipes 1, and generates electric power due to a temperature difference between the first fluid and a second fluid flowing outside the pipe 1. Further, the thermoelectric conversion element 2 has a sheet shape.

### TECHNICAL FIELD

The present invention relates to a thermoelectric conversion technique of acquiring electric power from waste heat, and particularly, relates to a thermoelectric conversion technique using a sheet-shaped thermoelectric conversion element.

### BACKGROUND ART

While an effort against an environmental or energy problem toward a sustainable society has been activated, expectation for a power generation system employing a thermoelectric conversion element is increasing. This is because heat is a most general energy source acquirable from all media such as a body temperature, sunlight, engine waste heat, and industrial waste heat. In particular, an effort for converting thermal energy of exhaust gas generated in an automobile, a steel station, and the like into electric power by a thermoelectric conversion element and reusing the energy has been actively carried out.

In such a power generation system, it is necessary to install power generation equipment such as a thermoelectric conversion element in a limited space in a vicinity of a flow path of exhaust gas, when thermal energy of exhaust gas is converted into electric power. In view of the above, it is desirable to set power generation efficiency to be high, while simplifying a configuration of power generation equipment such as a thermoelectric conversion element. Further, once a thermoelectric conversion element is installed in a vicinity of an exhaust gas pipe or the like, it is often the case that an operation such as repair becomes difficult, and thus high reliability is desirable.

As a technique for converting energy of exhaust gas generated from an automobile and the like into electric power, for example, a technique such as PTL 1 is disclosed. PTL 1 describes a waste heat power generation system in which power generation is performed by applying a thermoelectric conversion element to a temperature difference generated between exhaust gas of an automobile engine and cooling water.

Further, PTL 2 describes a thermoelectric generator which performs power generation by using thermal energy of exhaust gas. As illustrated in FIG. 12, the thermoelectric generator of PTL 2 includes an exhaust passage 13 of combustion gas, and an exhaust passage 13A, an exhaust passage 13B, and an exhaust passage 13C branched from the exhaust passage 13. Further, in the thermoelectric generator of PTL 2, a plurality of thermoelectric conversion elements 15 are mounted on a recess portion 14 of each exhaust passage. Each thermoelectric conversion element is formed by using a silicon substrate, and thermoelectric conversion elements 15 are connected to one another by an electrode. PTL 2 describes that having such a configuration enables effectively recovering thermal energy of exhaust gas.

Further, as a technique relating to a thermoelectric conversion element, techniques relating to a thermoelectric conversion element as described in PTL 3, and NPLs 1 and 2 are disclosed. PTL 3 describes a thermoelectric conversion element using a Peltier effect or a Seebeck effect. NPL 1 describes a thermoelectric conversion element using a spin Seebeck effect. Further, NPL 2 describes a thermoelectric conversion element using an anomalous Nernst effect. The thermoelectric conversion elements of PTL 3, and NPLs 1 and 2 are able to convert a heat flow generated in a direction perpendicular to a plane of a thermoelectric conversion element into current in a plane direction. Therefore, the thermoelectric conversion elements of PTL 3 and NPLs 1 and 2 are able to acquire a thermal electromotive force by disposing an electrode at both ends of a thermoelectric conversion element. Further, PTL 4 describes a thermoelectric power generation device employing two types of thermoelectric conversion elements in which a silicon germanium compound and a bismuth telluride compound are used as a thermoelectric element material.

### CITATION LIST

### Patent Literature

[PTL 1] Japanese Unexamined Patent Application Publication No. H08-261064
[PTL 2] Japanese Unexamined Patent Application Publication No. H07-12009
[PTL 3] Japanese Unexamined Patent Application Publication No.

2005-333083
[PTL 4] Japanese Unexamined Patent Application Publication No. 2000-286469

### Non Patent Literature

[NPL 1] Uchida et al., “Spin Seebeck Insulator”, Nature Materials, 2010, vol. 9, p. 894
[NPL 2] Sakuraba et al., “Anomalous Nernst Effect in L10-FePt/MnGa Termopiles for New Thermoelectric Applications”, Applied Physics Express, 2013, Volume 6, 0333003

### SUMMARY OF INVENTION

### Technical Problem

However, a technique described in each prior art document is not sufficient in the following point. The waste heat power generation system of PTL 1 performs power generation by using a thermoelectric conversion element at one location of each of a cooling water flow path and an exhaust flow path. Therefore, in the waste heat power generation system of PTL 1, power generation efficiency is low. Further, the thermoelectric generator of PTL 2 is configured in such a way that a plurality of thermoelectric elements formed on a silicon substrate are mounted on each branch pipe, and the thermoelectric conversion elements are connected to one another by an electrode. A thermoelectric conversion element formed on a silicon substrate has a large thickness, and requires a wide installation space. Further, since an electrode for connecting each of the thermoelectric conversion elements is necessary, a structure of the electrode becomes complicated, and a possibility of disconnection increases. The thermoelectric power generation device of PTL 4 also requires connecting a plurality of thermoelectric elements by an electrode, and involves an issue similar to the technique of PTL 2.

Further, even when the thermoelectric conversion element of one of PTL 3, and NPLs 1 and 2 is combined with the technique of PTL 2, it is difficult to simplify a configuration of an electrode for connecting thermoelectric conversion elements mounted on each branched exhaust passage. Therefore, complication of a structure of an electrode and disconnection occur. Thus, the technique described in each prior art document is not sufficient as a technique for efficiently performing power generation, based on thermal energy, while maintaining reliability without complicating a configuration.

In order to solve the above-described issue, an object of the present invention is to acquire a thermoelectric conversion unit, a power generation system, and a thermoelectric conversion method which are capable of efficiently performing power generation, based on thermal energy, while maintaining reliability without complicating a configuration.

### Solution to Problem

In order to solve the above-described issue, a thermoelectric conversion unit according to the present invention includes a plurality of pipes and a thermoelectric conversion element. A first fluid flows through the pipe. The thermoelectric conversion element is wound around each of the pipes, and configured to generate electric power, based on a temperature difference between the first fluid and a second fluid flowing outside a pipe 1. Further, the thermoelectric conversion element has a sheet shape.

Further, a thermoelectric conversion method according to the present invention includes: flowing a first fluid through a plurality of pipes; and generating electric power by a sheet-shaped thermoelectric conversion element wound around each of the pipes, based on a temperature difference between the first fluid and a second fluid flowing outside the pipe.

### Advantageous Effects of Invention

According to the present invention, it is possible to efficiently perform power generation, based on thermal energy, while maintaining reliability without complicating a configuration.

### BRIEF DESCRIPTION OF DRAWINGS

FIG. 1 is a diagram illustrating an overview of a configuration of a first example embodiment of the present invention.

FIG. 2A is a diagram illustrating an overview of a configuration of a second example embodiment of the present invention.

FIG. 2B is a cross-sectional view illustrating a structure of a thermoelectric conversion unit in the second example embodiment of the present invention.

FIG. 2C is a cross-sectional view illustrating a structure of the thermoelectric conversion unit in the second example embodiment of the present invention.

FIG. 3 is a diagram illustrating another configuration example of a branch exhaust gas pipe in the second example embodiment of the present invention.

FIG. 4A is a diagram illustrating another configuration example in the second example embodiment of the present invention.

FIG. 4B is a cross-sectional view illustrating a structure of a thermoelectric conversion unit as another configuration example in the second example embodiment of the present invention.

FIG. 4C is a cross-sectional view illustrating a structure of the thermoelectric conversion unit as another configuration example in the second example embodiment of the present invention.

FIG. 5 is a cross-sectional view illustrating a structure example of a thermoelectric conversion unit in the second example embodiment of the present invention.

FIG. 6A is a diagram illustrating an overview of a configuration of a third example embodiment of the present invention.

FIG. 6B is a cross-sectional view illustrating a structure of a thermoelectric conversion unit in the third example embodiment of the present invention.

FIG. 6C is a cross-sectional view illustrating a structure of the thermoelectric conversion unit in the third example embodiment of the present invention.

FIG. 7A is a diagram illustrating another configuration example in the third example embodiment of the present invention.

FIG. 7B is a cross-sectional view illustrating a structure of a thermoelectric conversion unit as another configuration example in the third example embodiment of the present invention.

FIG. 7C is a cross-sectional view illustrating a structure of the thermoelectric conversion unit as another configuration example in the third example embodiment of the present invention.

FIG. 8 is a diagram illustrating a structure example of a thermoelectric conversion element in the third example embodiment of the present invention.

FIG. 9 is a diagram illustrating a structure example of the thermoelectric conversion element in the third example embodiment of the present invention.

FIG. 10A is a diagram illustrating an overview of a configuration of a fourth example embodiment of the present invention.

FIG. 10B is a cross-sectional view illustrating a structure of a thermoelectric conversion unit in the fourth example embodiment of the present invention.

FIG. 10C is a cross-sectional view illustrating a structure of the thermoelectric conversion unit in the fourth example embodiment of the present invention.

FIG. 11A is a diagram illustrating an overview of a configuration of a fifth example embodiment of the present invention.

FIG. 11B is a cross-sectional view illustrating a structure of a thermoelectric conversion unit in the fifth example embodiment of the present invention.

FIG. 11C is a cross-sectional view illustrating a structure of the thermoelectric conversion unit in the fifth example embodiment of the present invention.

FIG. 12 is a diagram illustrating a configuration example of a thermoelectric conversion unit as a configuration in comparison with the present invention.

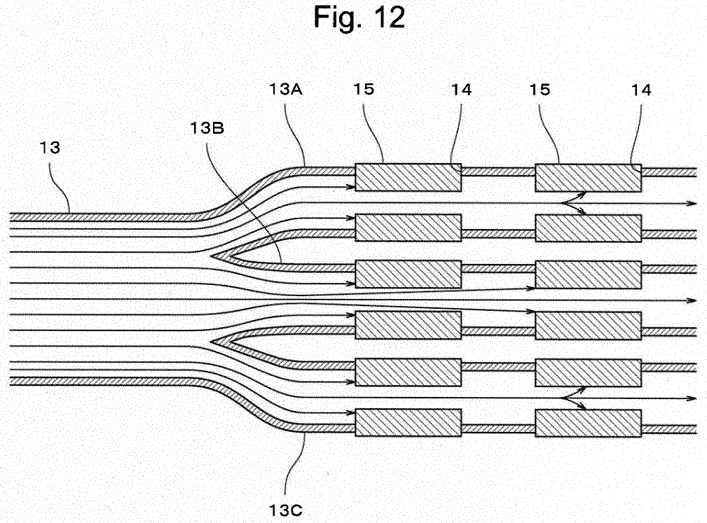

### EXAMPLE EMBODIMENT

### First Example Embodiment

### Configuration of First Example Embodiment

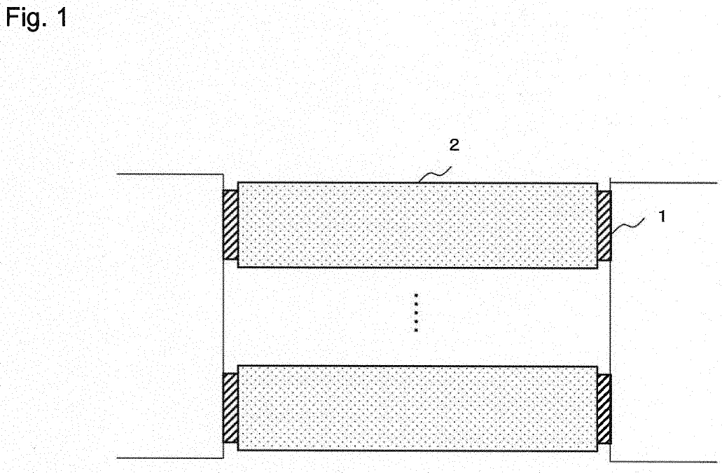

A first example embodiment according to the present invention is described in detail with reference to the drawings. FIG. 1 is a diagram illustrating an overview of a configuration of a thermoelectric conversion unit in the present example embodiment. The thermoelectric conversion unit in the present example embodiment includes a plurality of pipes 1 and a thermoelectric conversion element 2. A first fluid flows through the pipe 1. The thermoelectric conversion unit 2 is wound around each of the pipes 1, and generates electric power due to a temperature difference between the first fluid, and a second fluid flowing outside the pipe 1. Further, the thermoelectric conversion unit 2 has a sheet shape.

### Advantageous Effects of First Example Embodiment

The thermoelectric conversion unit in the present example embodiment is configured such that the sheet-shaped thermoelectric conversion element 2 is wound around each of the pipes 1. In the present example embodiment, since the thermoelectric conversion element 2 is wound around the pipe 1, it is possible to minimize a space required for disposing the thermoelectric conversion element 2 around the pipe 1. Further, employing the sheet-shaped thermoelectric conversion element 2 enables to continuously dispose the thermoelectric conversion element 2 along a longitudinal direction of the pipe 1, while covering an entirety of the pipe 1 in a circumferential direction thereof. Therefore, power generation efficiency improves, when power generation is performed based on a temperature difference between a first fluid and a second fluid. Further, since an electrode for connecting the thermoelectric conversion elements 2 within the same pipe 1 is not necessary, it is possible to suppress occurrence of disconnection and complication of a structure. Consequently, the thermoelectric conversion unit in the present example embodiment is able to efficiently perform power generation, based on thermal energy, while maintaining reliability without complicating a configuration.

### Second Example Embodiment

### Configuration of Second Example Embodiment

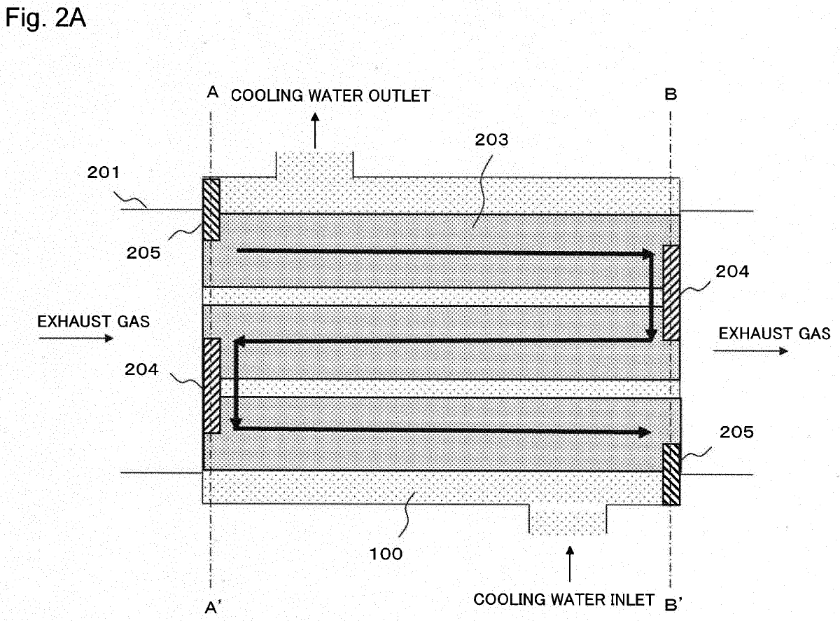

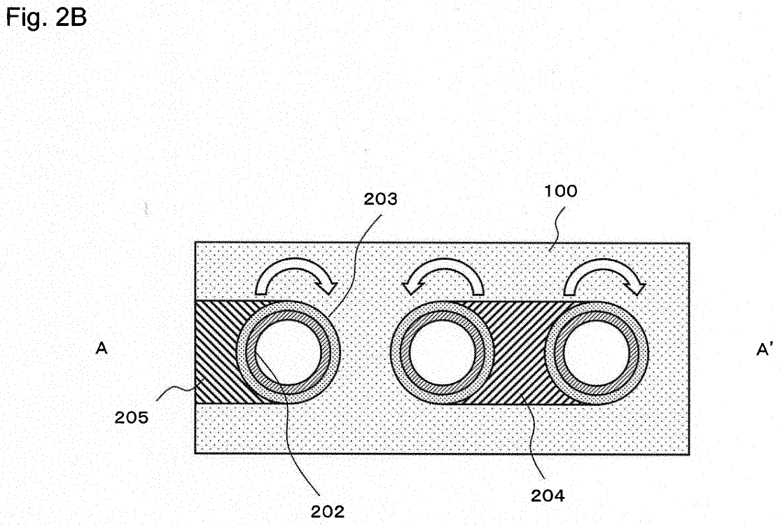

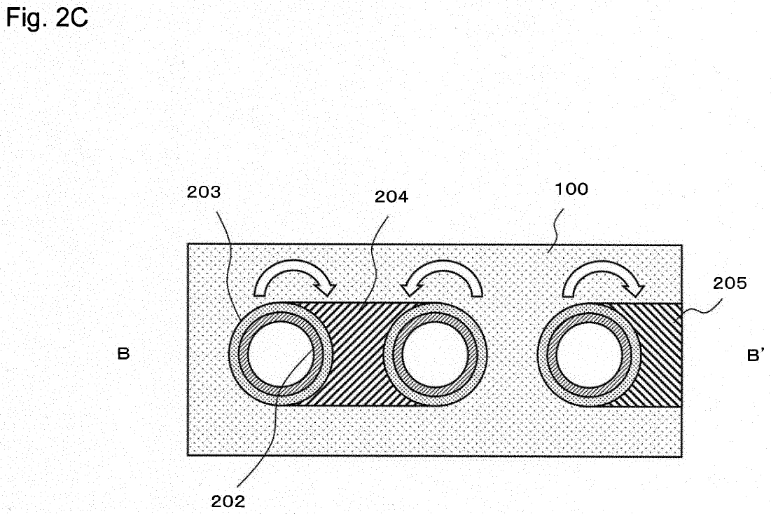

A second example embodiment according to the present invention is described in detail with reference to the drawings. FIG. 2A is a diagram illustrating an overview of a configuration of a power generation system of the present example embodiment. Further, FIGS. 2B and 2C are cross-sectional views of FIG. 2A. FIG. 2B is a cross-sectional view at a position along the line A-A′ in FIG. 2A. Further, FIG. 2C is a cross-sectional view at a position along the line B-B′ in FIG. 2A.

The power generation system of the present example embodiment includes a main exhaust gas pipe 201, a branch exhaust gas pipe 202, a sheet-shaped thermoelectric conversion element 203, an electric joint portion 204, and a terminal 205. The main exhaust gas pipe 201 is branched into a plurality of branch exhaust gas pipes 202. The sheet-shaped thermoelectric conversion element 203 is wound around the branch exhaust gas pipe 202. Winding means mounting a sheet of the sheet-shaped thermoelectric conversion element 203 in such a way as to wind along a surface of the branch exhaust gas pipe 202 in a circumferential direction thereof. Further, a vicinity of the branch exhaust gas pipe 202 and the sheet-shaped thermoelectric conversion element 203 is filled with circulating cooling water 100. Specifically, the sheet-shaped thermoelectric conversion element 203 is brought to a state such that a substantially entire surface of one of surfaces thereof comes into contact with the branch exhaust gas pipe 202, and a substantially entire surface of the other of the surfaces thereof is cooled by cooling water 100. The power generation system of the present example embodiment is able to generate electric power by the sheet-shaped thermoelectric conversion element 203, based on a temperature difference which exists between high-temperature exhaust gas and low-temperature cooling water 100.

The main exhaust gas pipe 201 is a pipe through which heated exhaust gas flows. A fluid such as heated gas and water vapor to be discharged from an internal combustion engine flows through the main exhaust gas pipe 201.

The branch exhaust gas pipes 202 are a plurality of pipes branched from the main exhaust gas pipe 201. The sheet-shaped thermoelectric conversion element 203 is wound around the branch exhaust gas pipe 202. The sheet-shaped thermoelectric conversion element 203 is wound around a circumference of the branch exhaust gas pipe 202. The branch exhaust gas pipes 202 are configured by branching the main exhaust gas pipe 201 into a plurality of pipes in a vicinity indicated in FIG. 2B. Further, the branch exhaust gas pipes 202 are joined in a vicinity indicated in FIG. 2C, and turns into the main exhaust gas pipe 201. Specifically, a fluid flowing through the main exhaust gas pipe 201 is separated into a plurality of branch exhaust gas pipes 202 at a branching portion. A fluid flowing through each of the branch exhaust gas pipes 202 merges at a connecting portion, and flows through the main exhaust gas pipe 201. Further, the branch exhaust gas pipe 202 in the present example embodiment corresponds to a pipe 1 in the first example embodiment.

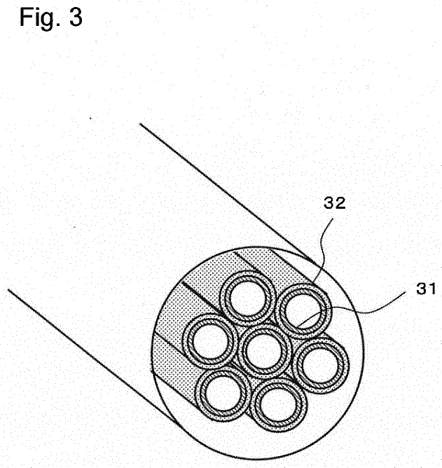

FIGS. 2A, 2B, and 2C illustrate an example in which the main exhaust gas pipe 201 is branched into three branch exhaust gas pipes 202, each of which has a circular cross section. FIGS. 2A, 2B, and 2C illustrate an example in which a plurality of branch exhaust gas pipes 202 are aligned one-dimensionally. Alternatively, a layout of branch exhaust gas pipes 202 may have a configuration other than the above. For example, as illustrated in FIG. 3, a plurality of branch exhaust gas pipes 31 may be configured to be bundled two-dimensionally. FIG. 3 illustrates an example in which the branch exhaust gas pipes 31, around each of which the sheet-shaped thermoelectric conversion element 32 is wound, are aligned two-dimensionally. Further, a number of branch exhaust gas pipes 202 may be four or more, or may be two. Furthermore, a cross-sectional shape of the branch exhaust gas pipe 202 may be a shape other than a circular shape. For example, a cross-sectional structure of the branch exhaust gas pipe 202 may have a square shape such as a quadrangular shape or a polygonal shape.

The main exhaust gas pipe 201 and the branch exhaust gas pipe 202 are made of a metal such as SUS, for example. A fluid flowing through the main exhaust gas pipe 201 and the branch exhaust gas pipe 202 may be liquid.

The sheet-shaped thermoelectric conversion element 203 is a thermoelectric conversion element in which current in an in-plane direction, specifically, a plane direction of a sheet, is generated due to a temperature gradient in a direction perpendicular to a plane of a sheet. A thermoelectric conversion element in which current flows in one direction among in-plane directions is employed, as the sheet-shaped thermoelectric conversion element 203. For example, it is possible to employ, as the sheet-shaped thermoelectric conversion element 203, a thermoelectric conversion element using a spin Seebeck effect or a thermoelectric conversion element using an anomalous Nernst effect.

A current generation direction in the sheet-shaped thermoelectric conversion element 203 is determined by a magnetization direction of the sheet-shaped thermoelectric conversion element 203. A blank arrow indicated in FIGS. 2B and 2C illustrates a magnetization direction of the sheet-shaped thermoelectric conversion element 203. Further, an arrow in FIG. 2A illustrates a current flow direction, which occurs due to a temperature difference. In this way, by magnetizing the sheet-shaped thermoelectric conversion element 203 in a circumferential direction of the branch exhaust gas pipe 202, current generated due to a temperature difference flows in a longitudinal direction of the branch exhaust gas pipe 202. Further, when a magnetization direction is reversed, a current generation direction is reversed. In view of the above, as illustrated in FIGS. 2B and 2C, alternating a magnetization direction of adjacent sheet-shaped thermoelectric conversion elements 203 also enables to alternate a current generation direction, as illustrated in FIG. 2A.

As illustrated in FIGS. 2B and 2C, when branch exhaust gas pipes 202, around each of the magnetized sheet-shaped thermoelectric conversion elements 203 is wound, are bundled, magnetization between adjacent sheet-shaped thermoelectric conversion elements 203 interact with each other in such a way as to cancel with each other. Therefore, when magnetization stability of the sheet-shaped thermoelectric conversion element 203 is considered, it is desirable to install each branch exhaust gas pipe 202 to be away from the adjacent branch exhaust gas pipe 202 by 10 micrometers or more.

Since a temperature of exhaust gas differs between a vicinity of an exhaust gas inlet and a vicinity of an exhaust gas outlet, a distribution of material composition suitable for the temperature distribution may be formed within the sheet-shaped thermoelectric conversion element 203. For example, regarding the vicinity of the exhaust gas inlet, thermoelectric conversion efficiency in a temperature range of the vicinity of the exhaust gas inlet is set higher than thermoelectric conversion efficiency in another temperature range. Regarding the vicinity of the exhaust gas inlet, material whose Curie temperature is higher than a temperature in the vicinity of the exhaust gas inlet is used. Further, regarding the vicinity of the exhaust gas outlet, thermoelectric conversion efficiency in a temperature range of the vicinity of the exhaust gas outlet is set higher than thermoelectric conversion efficiency in another temperature range. Regarding the vicinity of the exhaust gas outlet, material whose Curie temperature is higher than a temperature in the vicinity of the exhaust gas outlet is used.

The sheet-shaped thermoelectric conversion element 203 of the present example embodiment is brought to a state such that a substantially entire surface of one of surfaces thereof comes into contact with the branch exhaust gas pipe 202, and a substantially entire surface of the other of the surfaces thereof is cooled by cooling water 100. Therefore, it is possible to efficiently perform power generation, based on a temperature difference between gas flowing through the branch exhaust gas pipe 200, and cooling water 100. Since the sheet-shaped thermoelectric conversion element 203 is wound around the branch exhaust gas pipe 202, the sheet-shaped thermoelectric conversion element 203 is less likely to be detached, even when the branch exhaust gas pipe 202 is vibrated. Further, since the sheet-shaped thermoelectric conversion element 203 is wound around a substantially entire area of the branch exhaust gas pipe 202 in a longitudinal direction thereof, an electrode for connecting thermoelectric conversion elements within the branch exhaust gas pipe 202 may be degraded. Furthermore, since the sheet-shaped thermoelectric conversion element 203 is wound around the branch exhaust gas pipe 202, a wide space is not necessary in the vicinity of the branch exhaust gas pipe 202, when the branch exhaust gas pipe 202 is mounted. In addition, the sheet-shaped thermoelectric conversion element 203 in the present example embodiment corresponds to a thermoelectric conversion element 2 in the first example embodiment.

The electric joint portion 204 electrically connects each sheet-shaped thermoelectric conversion element 203 to one another. The electric joint portion 204 in the present example embodiment is mounted on an end of each sheet-shaped thermoelectric conversion element 203 in such a way that the adjacent sheet-shaped thermoelectric conversion elements 203 are electrically connected in series. It is desirable that the electric joint portion 204 is made of material having a low electrical resistance. The electric joint portion 204 is made of a metal such as Cu, Ag, Al, and Ti, or an alloy containing these elements, for example.

The terminal 205 is disposed as a connection terminal for extracting current to an outside from the sheet-shaped thermoelectric conversion elements 203 that are connected to be electrically in series. The terminal 205 is disposed at both end positions of the sheet-shaped thermoelectric conversion element 203 connected in series via the electric joint portion 204. The terminal 205 is connected to a circuit for transmitting electric power generated in the sheet-shaped thermoelectric conversion element 203, a battery for storing electric power, or the like.

Cooling water 100 is a fluid for cooling heated gas flowing through the branch exhaust gas pipe 202. In FIG. 2A, cooling water 100 flows in a direction opposite to a gas flow direction through the branch exhaust gas pipe 202, specifically, a direction of cooling water 100 and a direction of exhaust gas are opposite to each other. Flowing cooling water 100 and exhaust gas in directions opposite to each other improves cooling efficiency, since exhaust gas comes into contact with cooling water of a low temperature at a position where a temperature of exhaust gas is lowered in a vicinity of an outlet of the branch exhaust gas pipe 202. Directions opposing to each other may not be in parallel to each other, as far as cooling water 100 flows in such a way that a temperature of cooling water 100 in a surrounding of the branch exhaust gas pipe 202 lowers, as gas flows into the branch exhaust gas pipe 202. Further, since it is possible to keep a temperature difference between cooling water 100 and exhaust gas at both sides, namely, in the vicinity of the exhaust gas inlet and in the vicinity of the exhaust gas outlet of the branch exhaust gas pipe 202, power generation efficiency improves.

Cooling water 100 may flow in a same direction as a gas flow direction through the branch exhaust gas pipe 22, specifically, a direction of cooling water and a direction of exhaust gas may be the same as each other. Cooling water 100 may be liquid other than water, or may be a mixture of water and another substance. Further, air for performing air cooling may flow, in place of cooling water 100.

The power generation system of the present example embodiment is such that a thermoelectric conversion unit is constituted of a plurality of branch exhaust gas pipes 202, the sheet-shaped thermoelectric conversion element 203, the electric joint portion 204, the terminal 205, and the flow path of cooling water 100.

### Manufacturing Method and Operation of Second Example Embodiment

A method for configuring the power generation system of the present example embodiment is described. The following description is made based on a premise that connection between the main exhaust gas pipe 201 and the branch exhaust gas pipe 202 is performed in advance. First, the sheet-shaped thermoelectric conversion element 203 is formed. Since the sheet-shaped thermoelectric conversion element 203 comes into contact with cooling water when being operated, it is assumed that a surface of the sheet-shaped thermoelectric conversion element 203 is configured to be covered with a waterproof film. It is assumed that the sheet-shaped thermoelectric conversion element 203 is configured to be magnetized in an in-plane direction, specifically, in a plane direction of a sheet. Magnetization is performed by applying a magnetic field to a sheet on which a magnetic film is formed, for example.

The magnetized sheet-shaped thermoelectric conversion element 203 is wound around the branch exhaust gas pipe 202. Winding is performed in such a way that a magnetization direction of each sheet-shaped thermoelectric conversion element 203 is aligned with a circumferential shape of the branch exhaust gas pipe 202. Further, each of the sheet-shaped thermoelectric conversion elements 203 is wound in such a way that a magnetization direction in a circumferential direction becomes alternate between adjacent sheet-shaped thermoelectric conversion elements 203.

After each of the sheet-shaped thermoelectric conversion elements 203 are wound, the electric joint portion 204 is mounted on an end of the sheet-shaped thermoelectric conversion element 203 in such a way that the sheet-shaped thermoelectric conversion elements 203 are electrically connected in series. Further, in view of a possibility that the electric joint portion 204 may come into contact with cooling water 100, it is assumed that the electric joint portion 204 is configured to be covered with a waterproof film. After the electric joint portion 204 is mounted, the terminal 205 is mounted on the sheet-shaped thermoelectric conversion elements 203 at both ends among the electrically and serially connected sheet-shaped thermoelectric conversion elements 203. After the terminal 205 is mounted, cooling water 100 is introduced.

A method for configuring the power generation system may be performed by a method other than the above. For example, one end of the electric joint portion 204 may be connected in advance to one end of the predetermined sheet-shaped thermoelectric conversion element 203, in a stage of winding the sheet-shaped thermoelectric conversion element 203 around the branch exhaust gas pipe 202. Configuring as described above allows for an operator who performs a winding operation to perform the operation without confirming a magnetization direction, when winding is performed.

Further, in the foregoing description, winding of the sheet-shaped thermoelectric conversion element 203 around the branch exhaust gas pipe 202 that is mounted beforehand is performed. Alternatively, the branch exhaust gas pipe 202, around which the sheet-shaped thermoelectric conversion element 203 is wound, may be connected to the main exhaust gas pipe 201.

An operation of the power generation system of the present example embodiment is described. In the power generation system of the present example embodiment, high-temperature gas flows through the main exhaust gas pipe 201. Gas flowing through the main exhaust gas pipe 201 is separated into each of the branch exhaust gas pipes 202 at a branching portion between the main exhaust gas pipe 201 and each of the branch exhaust gas pipes 202, and flows through each branch exhaust gas pipe 202. Gas flowing through each branch exhaust gas pipe 202 merges at a connecting portion between each of the branch exhaust gas pipes 202 and the main exhaust gas pipe 201, and is discharged through the main exhaust gas pipe 201.

When gas flows through the branch exhaust gas pipe 202, a temperature difference occurs in the sheet-shaped thermoelectric conversion element 203 in a direction perpendicular to a plane of a sheet due to a temperature difference between gas and cooling water 100. A temperature difference in a direction perpendicular to a sheet generates current in the sheet-shaped thermoelectric conversion element 203 along a longitudinal direction of the branch exhaust gas pipe 202.

In the present example embodiment, the adjacent sheet-shaped thermoelectric conversion elements 203 are connected to each other by the electric joint portion 204, and a magnetization direction is set in such a way that current flows in directions opposite to each other with respect to a longitudinal direction of the branch exhaust gas pipe 202. Therefore, it is possible to extract, from both ends of a plurality of sheet-shaped thermoelectric conversion elements 203 in an electrically serial state, current flowing through each of the sheet-shaped thermoelectric conversion elements 203, via the terminal 205.

### Specific Example of Second Example Embodiment

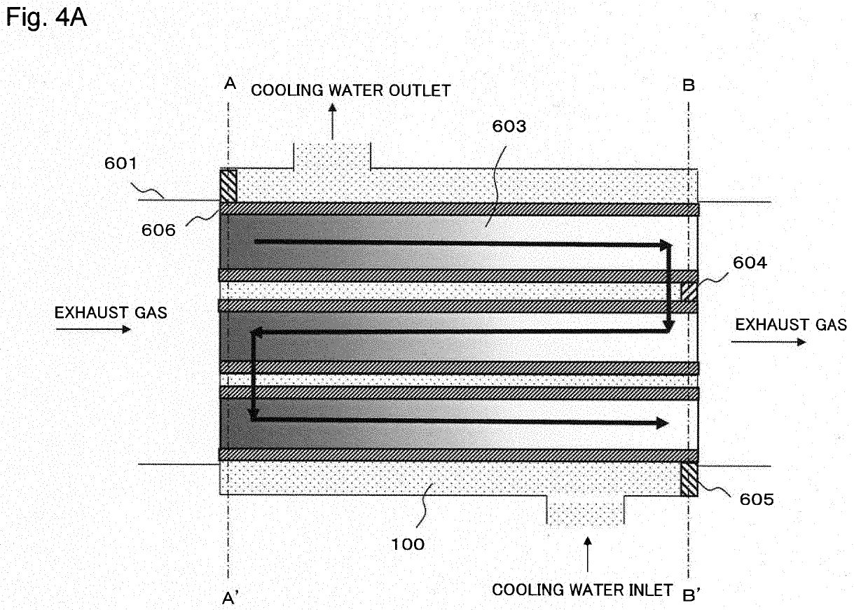

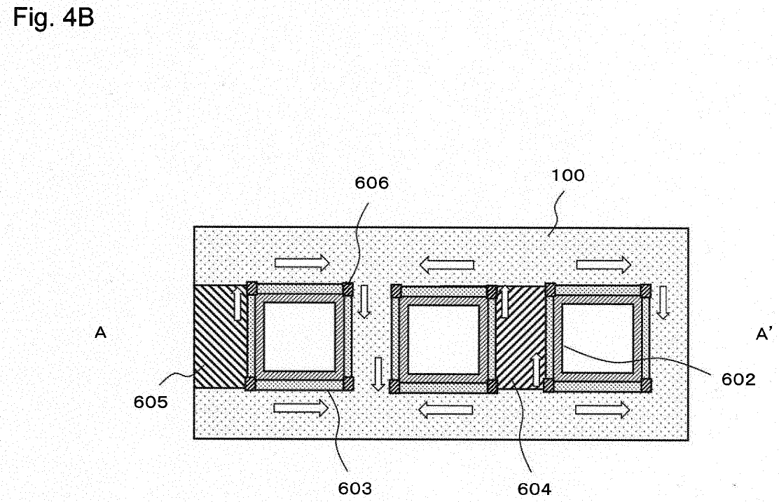

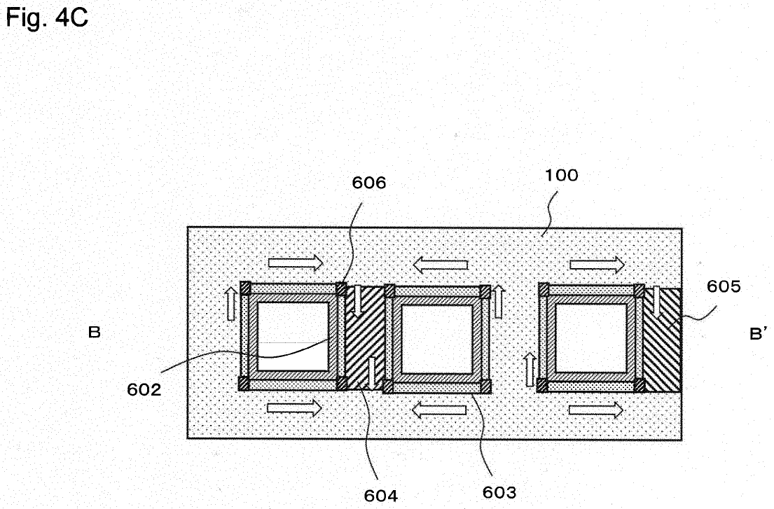

The power generation system of the second example embodiment is described by way of a more specific configuration as an example. FIG. 4A illustrates a configuration of a power generation system, when sheet-shaped anomalous Nernst thermoelectric conversion elements 603 using an anomalous Nernst effect are connected in series, as sheet-shaped thermoelectric conversion elements. Further, FIGS. 4B and 4C are cross-sectional views of FIG. 4A. FIG. 4B is a cross-sectional view at a position along the line A-A′ in FIG. 4A. Further, FIG. 4C is a cross-sectional view at a position along the line B-B′ in FIG. 4A.

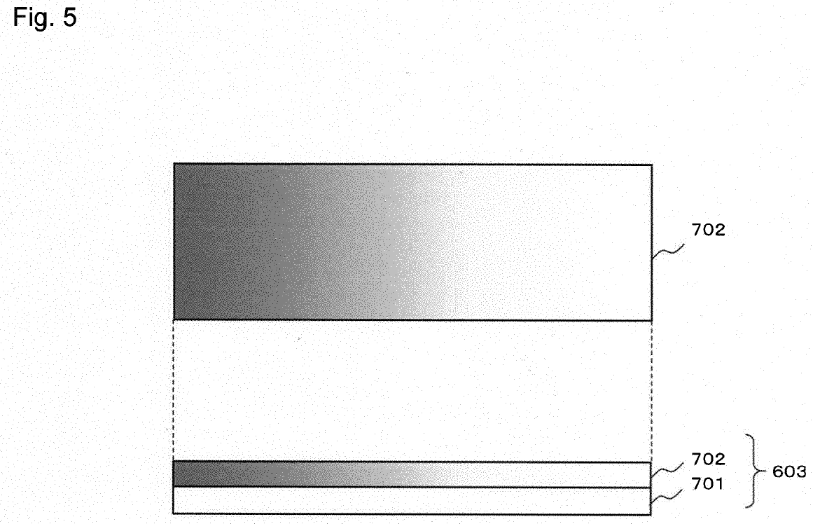

A method for manufacturing the sheet-shaped anomalous Nernst thermoelectric conversion element 603 is described. FIG. 5 illustrates a configuration of the sheet-shaped anomalous Nernst thermoelectric conversion element 603. The sheet-shaped anomalous Nernst thermoelectric conversion element 603 includes a substrate 701 and a magnetic film 702. An upper portion of FIG. 5 is a diagram of a plane of the sheet-shaped anomalous Nernst thermoelectric conversion element 603 when viewed from above. Further, a lower portion of FIG. 5 is a cross-sectional view of the sheet-shaped anomalous Nernst thermoelectric conversion element 603.

First, the magnetic film 702 is formed on the substrate 701, as an anomalous Nernst thermoelectric conversion film having a composition gradient. For example, an aluminum nitride substrate having a high temperature resistance and a high thermal conductivity is employed as the substrate 701. The magnetic film 702 is formed on a substrate 901 by a composition combinatorial sputtering method in which a composition gradient is formed. A composition combinatorial sputtering method is a method of forming a film having a composition gradient on a same substrate. The magnetic film 702 is formed on the sheet-shaped anomalous Nernst thermoelectric conversion element 603 in such a way that a composition gradient is formed in a longitudinal direction, when the branch exhaust gas pipe 602 is wound.

For example, an FeCoPt alloy film is employed as the magnetic film 702. The magnetic film 702 is formed in such a way that a Co-rich composition, specifically, a Co composition increases toward a left side in FIG. 5, and an Fe-rich composition, specifically, an Fe composition increases toward a right side. As a Co-rich composition increases, a Curie temperature rises, but thermoelectric conversion efficiency decreases. Conversely, as an Fe-rich composition increases, thermoelectric conversion efficiency increases, but a Curie temperature lowers.

After the magnetic film 702 is formed on the substrate 701, magnetization of the magnetic film 702 is performed. Magnetization is performed in an in-plane direction of the sheet-shaped anomalous Nernst thermoelectric conversion element 603, specifically, in a plane direction of a sheet. Further, magnetization is performed in a direction perpendicular to a direction of an Fe—Co composition gradient of the magnetic film 702.

The magnetized sheet-shaped anomalous Nernst thermoelectric conversion element 603 is mounted on the branch exhaust gas pipe 602. In the example of FIGS. 4B and 4C, a cross-sectional shape of the branch exhaust gas pipe 602 is a quadrangular shape. Therefore, four sheet-shaped anomalous Nernst thermoelectric conversion elements 603 are mounted on one branch exhaust gas pipe 602. Mounting of the sheet-shaped anomalous Nernst thermoelectric conversion elements 603 is performed in such a way that a direction of an Fe—Co composition gradient is aligned with a longitudinal direction of the branch exhaust gas pipe 602. Further, mounting is performed in such a way that an exhaust gas inlet side, specifically, a vicinity indicated in FIG. 4B corresponds to a Co-rich composition, and a vicinity of an exhaust gas outlet, specifically, a vicinity indicated in FIG. 4C corresponds to an Fe-rich composition.

Further, a magnetization direction of the sheet-shaped anomalous Nernst thermoelectric conversion element 603 wound around each branch exhaust gas pipe 602 is configured to be alternate between the adjacent branch exhaust gas pipes 602. For example, a magnetization direction of the leftmost branch exhaust gas pipe 602 in FIG. 4B is clockwise, a magnetization direction of the middle branch exhaust gas pipe 602 is counterclockwise, and a magnetization direction of the rightmost branch exhaust gas pipe 602 is clockwise.

After the sheet-shaped anomalous Nernst thermoelectric conversion element 603 is mounted, an electric joint portion 606 made of Cu is mounted in such a way that four sheet-shaped anomalous Nernst thermoelectric conversion elements 603 are electrically connected to four corners of each branch exhaust gas pipe 802.

After the electric joint portion 606 is mounted on four corners of each branch exhaust gas pipe 602, mounting of an electric joint portion 604 made of Cu is performed in such a way that the branch exhaust gas pipes 602 are electrically connected in series. Further, portions of the sheet-shaped anomalous Nernst thermoelectric conversion element 603, the electric joint portion 604, and the electric joint portion 606, except for electrically jointed portions, are covered with a waterproof film so as not to contact with cooling water.

When high-temperature exhaust gas flows in the power generation system as described above, power generation is performed by the sheet-shaped anomalous Nernst thermoelectric conversion element 603, based on a temperature difference between the branch exhaust gas pipe 602 and cooling water 100, and it is possible to extract electric power of the power generation system from a terminal 605.

FIGS. 4A, 4B, and 4C illustrate a structure in which a main exhaust gas pipe 601 is branched into three branch exhaust gas pipes 602, each of which has a quadrangular cross section, and the branch exhaust gas pipes 602 are aligned one-dimensionally. A number and a layout of branch exhaust gas pipes 602 may have a structure other than the above. For example, a number of branch exhaust gas pipes 602 may be a number other than three. As illustrated in FIG. 3, the branch exhaust gas pipes 602 may be configured to be bundled two-dimensionally. Further, a cross-sectional structure of an exhaust gas pipe may not have a quadrangular shape, but may have a polygonal shape or a circular shape.

In FIGS. 4A, 4B, and 4C, the sheet-shaped anomalous Nernst thermoelectric conversion element 603 is mounted on each surface of the branch exhaust gas pipe 602, and the sheet-shaped anomalous Nernst thermoelectric conversion elements 603 are electrically connected to one another by the electric joint portion 606. Alternatively, the sheet-shaped anomalous Nernst electric conversion element 603 having a plurality of surfaces may be continued.

In FIG. 4A, flowing directions of cooling water 100 are opposite to each other. Alternatively, flowing directions may be the same. Further alternatively, an air-cooling method may be employed, in place of a cooling method by cooling water 100. Furthermore alternatively, high-temperature liquid may flow through the main exhaust gas pipe 601 and the branch exhaust gas pipe 602, in place of exhaust gas.

### Advantageous Effects of Second Example Embodiment

In the power generation system of the present example embodiment, a sheet-shaped thermoelectric conversion element is wound around a plurality of branch exhaust gas pipes branched from a main exhaust gas pipe. Since employing the sheet-shaped thermoelectric conversion element can suppress an increase in space, when the sheet-shaped thermoelectric conversion element is mounted on the branch exhaust gas pipe, it becomes possible to densely dispose the branch exhaust gas pipes. In the power generation system of the present example embodiment, by densely disposing the branch exhaust gas pipes branched from the main exhaust gas pipe, a surface area where the sheet-shaped thermoelectric conversion element and the branch exhaust gas pipe come into contact with each other increases. Further, even for one branch exhaust gas pipe, an area where the sheet-shaped thermoelectric conversion element and the branch exhaust gas pipe come into contact with each other over the entirety of a circumference thereof is wide. Therefore, the power generation system of the present example embodiment has high power generation efficiency.

Further, in the power generation system of the present example embodiment, the sheet-shaped thermoelectric conversion element is wound in such a way as to come into contact with an entirety of a circumference of the branch exhaust gas pipe. Therefore, even when vibration occurs in the branch exhaust gas pipe, detachment of the sheet-shaped thermoelectric conversion element from the branch exhaust gas pipe is less likely to occur.

Further, since the sheet-shaped thermoelectric conversion element is continuously wound in a longitudinal direction of the branch exhaust gas pipe, an electrode for connecting thermoelectric conversion elements within a same branch exhaust gas pipe is not necessary. Therefore, in the power generation system of the present example embodiment, reliability improves by suppressing occurrence of disconnection or detachment, while simplifying a configuration. Consequently, the power generation system of the present example embodiment is able to efficiently perform power generation, based on thermal energy, while maintaining reliability without complicating a configuration.

### Third Example Embodiment

### Configuration of Third Example Embodiment

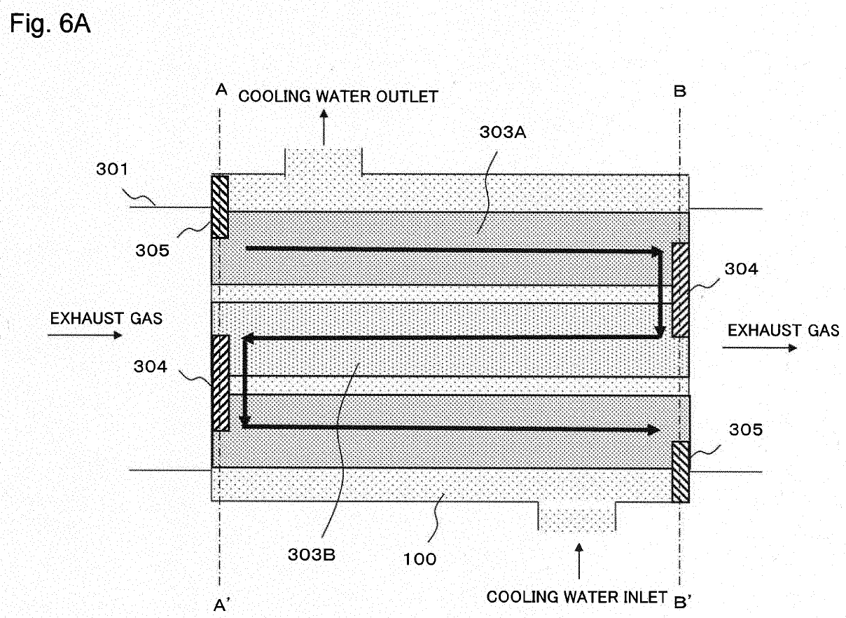

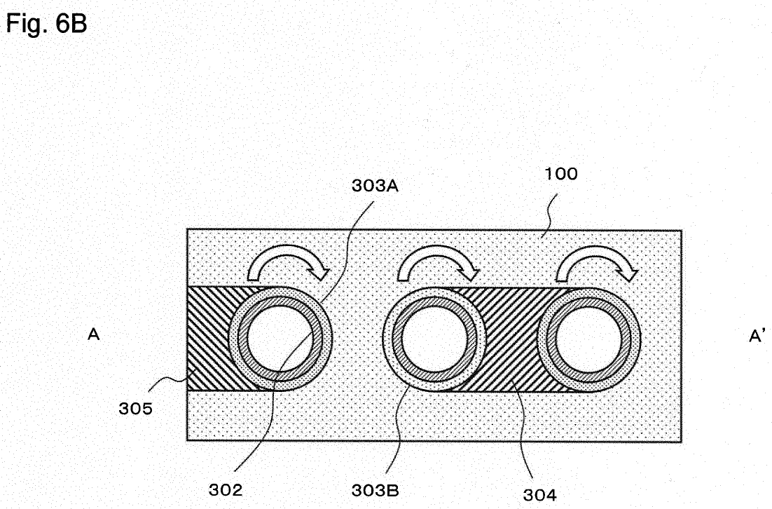

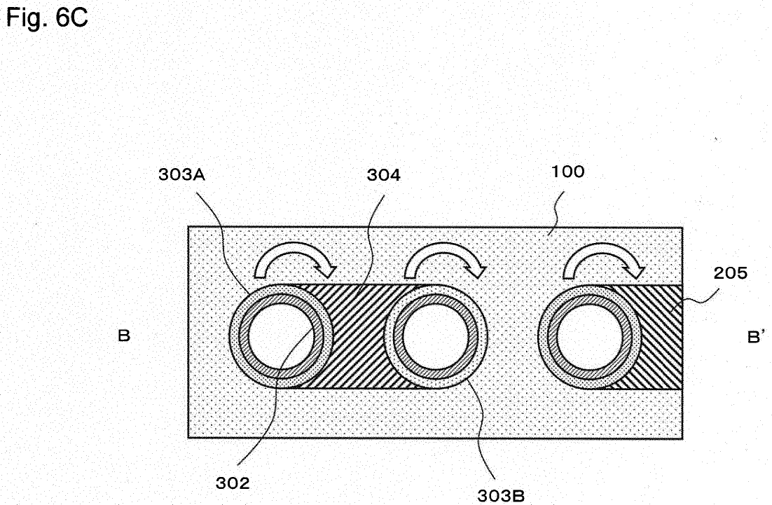

A third example embodiment according to the present invention is described in detail with reference to the drawings. FIG. 6A is a diagram illustrating an overview of a configuration of a power generation system of the present example embodiment. Further, FIGS. 6B and 6C are cross-sectional views of FIG. 6A. FIG. 6B is a cross-sectional view at a position along the line A-A′ in FIG. 6A. Further, FIG. 6C is a cross-sectional view at a position along the line B-B′ in FIG. 6A.

The power generation system of the present example embodiment includes a main exhaust gas pipe 301, a branch exhaust gas pipe 302, a first sheet-shaped thermoelectric conversion element 303A, a second sheet-shaped thermoelectric conversion element 303B, an electric joint portion 304, and a terminal 305. A vicinity of the branch exhaust gas pipe 302 and each sheet-shaped thermoelectric conversion element is filled with circulating cooling water 100.

The power generation system of the second example embodiment has a configuration in which a current flow direction with respect to a magnetization direction is the same, and current flows in opposite directions between adjacent sheet-shaped thermoelectric conversion elements depending on a direction along which a sheet-shaped thermoelectric conversion element is mounted. However, in place of such a configuration, the present example embodiment has a feature that a sheet-shaped thermoelectric conversion element is formed by using material such that a current flow direction becomes opposite even with respect to a same magnetization direction.

A configuration of the main exhaust gas pipe 301 and a configuration of the branch exhaust gas pipe 302 are respectively the same as those of a main exhaust gas pipe 201 and a branch exhaust gas pipe 202 in the second example embodiment.

Similarly to a sheet-shaped thermoelectric conversion element 203 in the second example embodiment, the first sheet-shaped thermoelectric conversion element 303A and the second sheet-shaped thermoelectric conversion element 303B are thermoelectric conversion elements in which current in an in-plane direction is generated due to a temperature gradient in a direction perpendicular to a plane of a sheet. The first sheet-shaped thermoelectric conversion element 303A and the second sheet-shaped thermoelectric conversion element 303B are formed as thermoelectric conversion elements using a spin Seebeck effect, for example.

Materials used for the first sheet-shaped thermoelectric conversion element 303A and the second sheet-shaped thermoelectric conversion element 303B are different from each other. The first sheet-shaped thermoelectric conversion element 303A is made of material in which a spin Hall angle is positive. Further, the second sheet-shaped thermoelectric conversion element 303B is made of material in which a spin Hall angle is negative. When signs of spin Hall angles differ, current generation directions become opposite to each other even with respect to a same magnetization direction.

The first sheet-shaped thermoelectric conversion element 303A and the second sheet-shaped thermoelectric conversion element 303B are alternately wound around the branch exhaust gas pipe 302. Since a vicinity of the first sheet-shaped thermoelectric conversion element 303A and the second sheet-shaped thermoelectric conversion element 303B is filled with circulating cooling water 100, the first sheet-shaped thermoelectric conversion element 303A and the second sheet-shaped thermoelectric conversion element 303B are able to perform power generation due to a temperature difference which exists between high-temperature exhaust gas and low-temperature cooling water 100.

The first sheet-shaped thermoelectric conversion element 303A and the second sheet-shaped thermoelectric conversion element 303B are magnetized in a circumferential direction of the branch exhaust gas pipe 302. Therefore, current generated due to a temperature difference between exhaust gas and cooling water 100 is generated in a longitudinal direction of the branch exhaust gas pipe 302.

Further, although magnetization directions in a circumferential direction of the first sheet-shaped thermoelectric conversion element 303A and the second sheet-shaped thermoelectric conversion element 303B are the same, spinning signs of materials thereof are different from each other. Therefore, directions of current generated in the first sheet-shaped thermoelectric conversion element 303A and the second sheet-shaped thermoelectric conversion element 303B become opposite to each other.

Since a temperature of exhaust gas differs between a vicinity of an exhaust gas inlet and a vicinity of an exhaust gas outlet, a distribution of material composition suitable for a temperature distribution may be formed in the first sheet-shaped thermoelectric conversion element 303A and the second sheet-shaped thermoelectric conversion element 303B, similarly to the second example embodiment. For example, the vicinity of the exhaust gas inlet is formed by using material such that thermoelectric conversion efficiency in a temperature range of the vicinity of the exhaust gas inlet is higher than thermoelectric conversion efficiency in another temperature range, and a Curie temperature is higher than a temperature in the vicinity of the exhaust gas inlet. Further, the vicinity of the exhaust gas outlet is formed by using material such that thermoelectric conversion efficiency in a temperature range of the vicinity of the exhaust gas outlet is higher than thermoelectric conversion efficiency in another temperature range, and a Curie temperature is higher than a temperature in the vicinity of the exhaust gas outlet.

The electric joint portion 304 is mounted in such a way that each of the sheet-shaped thermoelectric conversion elements are electrically connected in series at an end of each of the first sheet-shaped thermoelectric conversion element 303A and the second sheet-shaped thermoelectric conversion element 303B. It is desirable that the electric joint portion 304 is made of material having a low electrical resistance. For example, the electric joint portion 304 is made of a metal such as Cu, Ag, Al, and Ti, or an alloy containing these elements.

The terminal 305 is disposed as a connection terminal for extracting current to an outside from the sheet-shaped thermoelectric conversion elements that are connected to be electrically in series.

As illustrated in FIGS. 6B and 6C, when the branch exhaust gas pipes 302, around each of which the magnetized first sheet-shaped thermoelectric conversion element 303A and the magnetized second sheet-shaped thermoelectric conversion element 303B are wound, are bundled, magnetization between adjacent sheet-shaped thermoelectric conversion elements interact with each other in such a way as to reinforce each other. Therefore, when magnetization stability of the first sheet-shaped thermoelectric conversion element 303A and the second sheet-shaped thermoelectric conversion element 303B is considered, it is desirable to set a distance between the branch exhaust gas pipes 302 to 10 centimeters or less.

Further, in order to enhance magnetization stability of the first sheet-shaped thermoelectric conversion element 303A and the second sheet-shaped thermoelectric conversion element 303B, a fluid having a high permeability as compared with water may be used as cooling water 100. As an example of a fluid having a high permeability as compared with water, it is possible to use a magnetic fluid acquired by mixing ferromagnetic particles such as magnetite or manganese zinc ferrite in liquid, or a magneto rheological (MR) fluid.

FIGS. 6A, 6B, and 6C illustrate a configuration in which the main exhaust gas pipe 301 is branched into three branch exhaust gas pipes 302, each of which has a circular cross section, and the branch exhaust gas pipes 302 are aligned one-dimensionally. A number of branch exhaust gas pipes 302 may be a number other than three, in place of such a configuration. Further, each of the branch exhaust gas pipes 302 may be configured to be bundled two-dimensionally. Furthermore, a cross-sectional structure of the branch exhaust gas pipe 302 may not have a circular shape, but may have a square shape such as a quadrangular shape.

FIG. 6A illustrates a configuration that cooling water 100 flows in an opposite direction. Alternatively, cooling water may flow in a same direction as a direction of exhaust gas. Further, cooling by air-cooling may be performed, in place of a cooling method employing cooling water 100.

### Manufacturing Method and Operation of Third Example Embodiment

A method for configuring the power generation system of the present example embodiment is described. The following description is made based on a premise that connection between the main exhaust gas pipe 301 and the branch exhaust gas pipe 302 is performed in advance. First, the first sheet-shaped thermoelectric conversion element 303A and the second sheet-shaped thermoelectric conversion element 303B are formed.

The first sheet-shaped thermoelectric conversion element 303A and the second sheet-shaped thermoelectric conversion element 303B are formed of materials whose signs of spin Hall angles are different from each other. For example, the first sheet-shaped thermoelectric conversion element 303A is made of material in which a spin Hall angle is positive such as metals Pt, Au, Co, Ni, and Ag, or an alloy containing these elements. Further, the second sheet-shaped thermoelectric conversion element 303B is made of material in which a spin Hall angle is negative such as metals W, Fe, Mn, Ru, Os, and Cr, or an alloy containing these elements. Further, since the first sheet-shaped thermoelectric conversion element 303A and the second sheet-shaped thermoelectric conversion element 303B come into contact with cooling water when being operated, a surface of each of the first sheet-shaped thermoelectric conversion element 303A and the second sheet-shaped thermoelectric conversion element 303B is covered with a waterproof film.

After a magnetic film is formed, the first sheet-shaped thermoelectric conversion element 303A and the second sheet-shaped thermoelectric conversion element 303B are magnetized in an in-plane direction. After magnetization is performed, the first sheet-shaped thermoelectric conversion element 303A and the second sheet-shaped thermoelectric conversion element 303B are wound around the branch exhaust gas pipe 302. Winding is performed in such a way that magnetization directions of the first sheet-shaped thermoelectric conversion element 303A and the second sheet-shaped thermoelectric conversion element 303B are aligned with a circumferential shape of the branch exhaust gas pipe 302, and magnetization directions in a circumferential direction become the same among sheet-shaped spin thermoelectric conversion elements.

After winding is performed, the electric joint portion 304 is mounted on an end of each sheet-shaped thermoelectric conversion element in such a way that the first sheet-shaped thermoelectric conversion element 303A and the second sheet-shaped thermoelectric conversion element 303B are alternately and serially connected. Further, in view of a possibility that the electric joint portion 304 may come into contact with cooling water, the electric joint portion 304 is covered with a waterproof film. Furthermore, the power generation system may be configured by a method other than the above.

After the electric joint portion 304 is mounted, the terminal 305 for extracting electric power to an outside is mounted on the sheet-shaped thermoelectric conversion elements serving as both ends, when the sheet-shaped thermoelectric conversion elements are connected in series. After the electric joint portion 304 is mounted, a flow path of cooling water 100 is formed. The terminal 305 is connected to a circuit or a battery serving as a supply destination of electric power.

An operation of the power generation system of the present example embodiment is described. In the power generation system of the present example embodiment, high-temperature gas flows through the main exhaust gas pipe 301. Gas flowing through the main exhaust gas pipe 301 is separated into each of the branch exhaust gas pipes 302 at a connecting portion between the main exhaust gas pipe 301 and each of the branch exhaust gas pipes 302, and flows through each branch exhaust gas pipe 302. Gas flowing through each branch exhaust gas pipe 302 merges at a connecting portion between each of the branch exhaust gas pipes 302 and the main exhaust gas pipe 301, and is discharged through the main exhaust gas pipe 301.

When gas flows through the branch exhaust gas pipe 302, a temperature difference occurs in a direction perpendicular to a plane of a sheet of each of the first sheet-shaped thermoelectric conversion element 303A and the second sheet-shaped thermoelectric conversion element 303B due to a temperature difference between exhaust gas and cooling water 100. A temperature difference in a direction perpendicular to a sheet generates current in the first sheet-shaped thermoelectric conversion element 303A and the second sheet-shaped thermoelectric conversion element 303B along a longitudinal direction of the branch exhaust gas pipe 302. Further, since signs of spin Hall angles are opposite between the first sheet-shaped thermoelectric conversion element 303A and the second sheet-shaped thermoelectric conversion element 303B, current flow directions become opposite to each other with respect to a longitudinal direction.

In the present example embodiment, the adjacent sheet-shaped thermoelectric conversion elements are connected to each other by the electric joint portion 304, and current flows in directions opposite to each other with respect to a longitudinal direction of the branch exhaust gas pipe 302. Therefore, it is possible to acquire electric power by extracting current flowing alternately through the first sheet-shaped thermoelectric conversion element 303A and the second sheet-shaped thermoelectric conversion element 303B, via the terminal 505.

### Specific Example of Third Example Embodiment

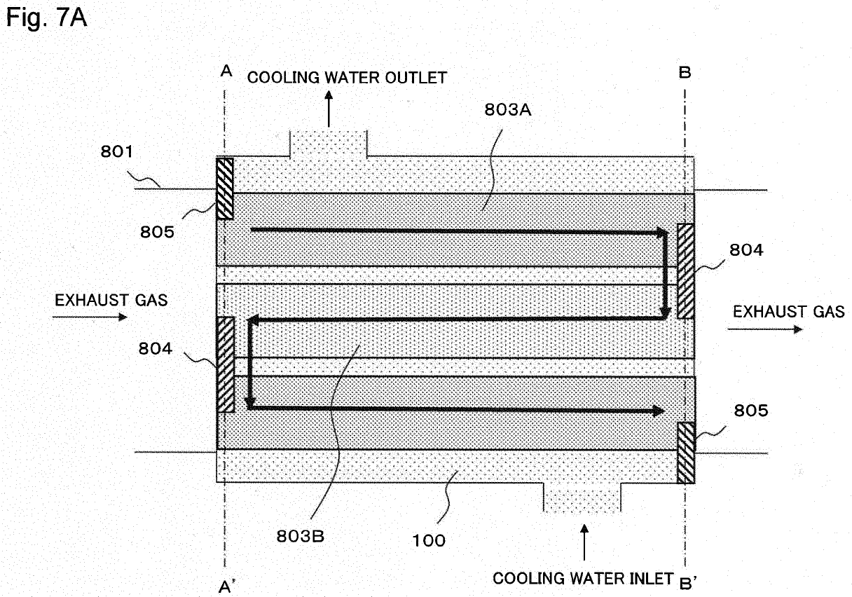

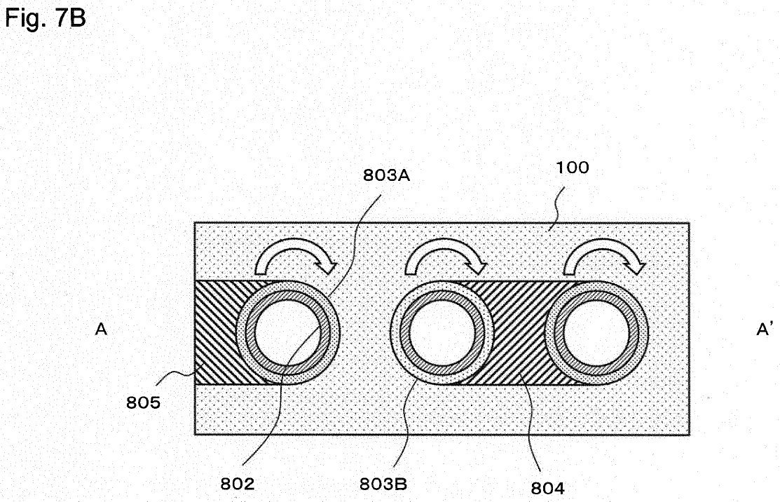

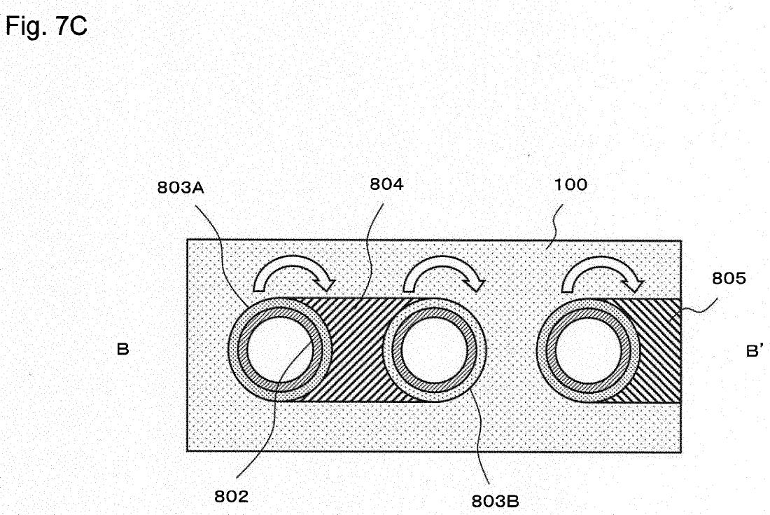

The power generation system of the third example embodiment is described, based on a more specific example. FIG. 7A is a diagram illustrating a configuration of the power generation system, when sheet-shaped spin Seebeck thermoelectric conversion elements whose signs of spin Hall angles are different from each other are alternately connected in series, as sheet-shaped thermoelectric conversion elements. A sheet-shaped spin Seebeck thermoelectric conversion element 803A corresponds to the first sheet-shaped thermoelectric conversion element 303A. A sheet-shaped spin Seebeck thermoelectric conversion element 803B corresponds to the second sheet-shaped thermoelectric conversion element 303B. Further, FIGS. 7B and 7C are cross-sectional views of FIG. 7A. FIG. 7B is a cross-sectional view at a position along the line A-A′ in FIG. 7A. Furthermore, FIG. 7C is a cross-sectional view at a position along the line B-B′ in FIG. 7A.

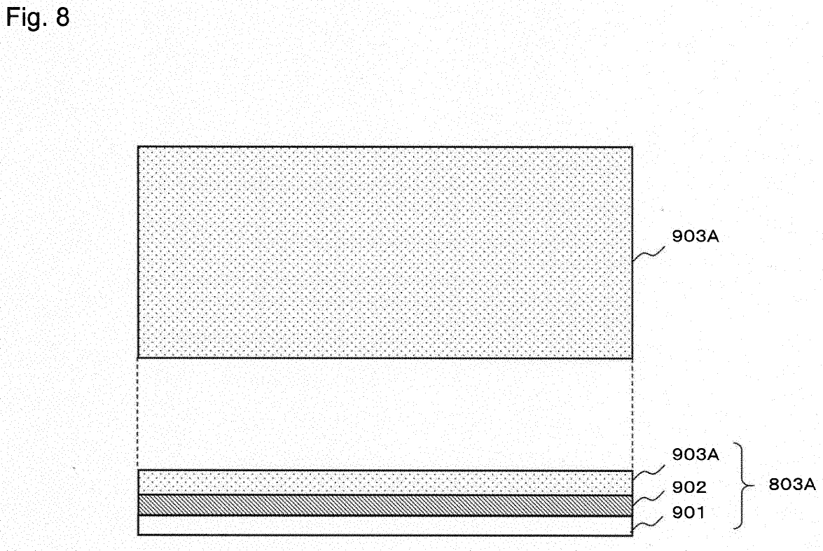

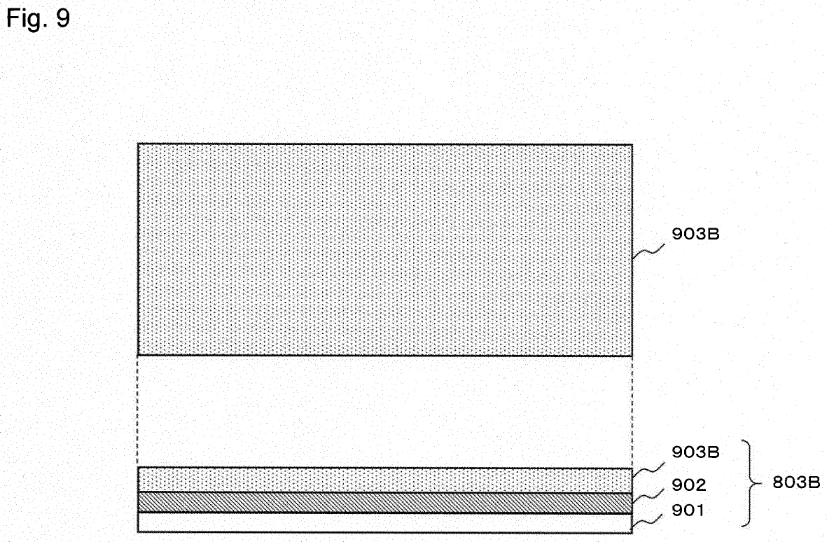

A method for manufacturing the sheet-shaped spin Seebeck thermoelectric conversion element 803A and the sheet-shaped spin Seebeck thermoelectric conversion element 803B is described. FIG. 8 is a diagram illustrating a configuration of the sheet-shaped spin Seebeck thermoelectric conversion element 803A. Further, FIG. 9 is a diagram illustrating a configuration of the sheet-shaped spin Seebeck thermoelectric conversion element 803B. An upper portion of each of FIGS. 8 and 9 is a diagram of a plane of the sheet-shaped Seebeck thermoelectric conversion element when viewed from above. Further, a lower portion of each of FIGS. 8 and 9 is a cross-sectional view of the sheet-shaped Seebeck thermoelectric conversion element.

First, a magnetic insulation film 902, and a metal film 903A or a metal film 903 are formed on a substrate 901. A flexible sheet containing MN particles is employed as the substrate 901, for example. The magnetic insulation film 902 is formed on the substrate 901. For example, NiZn is formed on the magnetic insulation film 902 by a ferrite plating method. A ferrite plating method is a method of forming a flexible ferrite film.

After the magnetic insulation film 902 is formed, the metal film 903A or the metal film 903B is formed on the magnetic insulation film 902 by a sputtering method. Material whose sign of a spin Hall angle is positive is used for the metal film 903A. Pt whose sign of a spin Hall angle is positive is used for the metal film 903A, for example. Further, material whose sign of a spin Hall angle is negative is used for the metal film 903B. W whose sign of a spin Hall angle is negative is used for the metal film 903B, for example.

After the metal film 903A or the metal film 903B is formed, magnetization of the sheet-shaped Seebeck thermoelectric conversion element 803A or the sheet-shaped Seebeck thermoelectric conversion element 803B in an in-plane direction is performed.

The magnetized sheet-shaped spin Seebeck thermoelectric conversion elements 803A and 803B are mounted on the branch exhaust gas pipe 802. When mounting is performed, the sheet-shaped spin Seebeck thermoelectric conversion elements 803A and 803B are wound around the branch exhaust gas pipe 802 in such a way that magnetization directions are aligned with a circumferential direction of the branch exhaust gas pipe 802. Further, the sheet-shaped spin Seebeck thermoelectric conversion elements 803A and 803B are disposed in such a way as to be alternate, and are wound around the branch exhaust gas pipe 802 in such a way that magnetization directions in a circumferential direction become the same.

The sheet-shaped spin Seebeck thermoelectric conversion element 803A is wound around the leftmost branch exhaust gas pipe 802 in FIGS. 7B and 7C, and the sheet-shaped spin Seebeck thermoelectric conversion element 803B is wound around the middle branch exhaust gas pipe 802. The sheet-shaped spin Seebeck thermoelectric conversion element 803A is wound around the rightmost branch exhaust gas pipe 802 in FIGS. 7B and 7C. Further, magnetization directions of all sheet-shaped spin Seebeck thermoelectric conversion elements 803A and 803B are clockwise.

After winding is finished, mounting of the electric joint portion 804 made of Cu is performed, for example, in such a way that the sheet-shaped spin Seebeck thermoelectric conversion elements 803A and 803B are electrically and serially connected. Further, a magnetic fluid containing magnetite particles is used as cooling water 100, for example.

Each of the sheet-shaped spin Seebeck thermoelectric conversion element 803A, the sheet-shaped spin Seebeck thermoelectric conversion element 803B, and the electric joint portion 804 is covered with a waterproof film so as not to contact with a magnetic fluid. After the electric joint portion 840 is mounted, the terminal 805 is mounted on the spin Seebeck thermoelectric conversion elements serving as both ends, when the spin Seebeck thermoelectric conversion elements are connected in series.

When high-temperature exhaust gas flows through the above-described power generation system, power generation is performed in the sheet-shaped spin Seebeck thermoelectric conversion elements 803A and 803B due to a temperature difference between the branch exhaust gas pipe 802, and a magnetic fluid being cooling water 100. Electric power generated in the sheet-shaped spin Seebeck thermoelectric conversion elements 803A and 803B is extractable and usable via the terminal 805.

FIGS. 7A, 7B, and 7C illustrate a configuration in which the main exhaust gas pipe 801 is branched into three branch exhaust gas pipes 802, each of which has a circular cross section, and the branch exhaust gas pipes 802 are aligned one-dimensionally. A number of branch exhaust gas pipes 802 may be a number other than three, and the branch exhaust gas pipes 802 may be configured to be bundled two-dimensionally. Further, a cross-sectional structure of an exhaust gas pipe may not have a circular shape, but may have a square shape such as a quadrangular shape. In FIG. 7A, cooling water 100 flows in an opposite direction, but may flow in the same direction as a direction of exhaust gas. Further, an air-cooling method may be employed, in place of a cooling method by cooling water. Furthermore, high-temperature liquid may flow through the main exhaust gas pipe 801 and the branch exhaust gas pipe 802, in place of exhaust gas.

### Advantageous Effects of Third Example Embodiment

The power generation system of the present example embodiment has advantageous effects similar to those of the second example embodiment. Specifically, the power generation system of the present example embodiment is able to efficiently perform power generation, based on thermal energy, while maintaining reliability without complicating a configuration. Further, in the power generation system of the present example embodiment, generated current flows in directions opposite to each other by employing the sheet-shaped thermoelectric conversion elements made of materials whose spin Hall angles are different from each other. Therefore, in the power generation system of the present example embodiment, since magnetization directions of all sheet-shaped thermoelectric conversion elements become the same, it is possible to suppress complication when an operation is performed.

### Fourth Example Embodiment

### Configuration of Fourth Example Embodiment

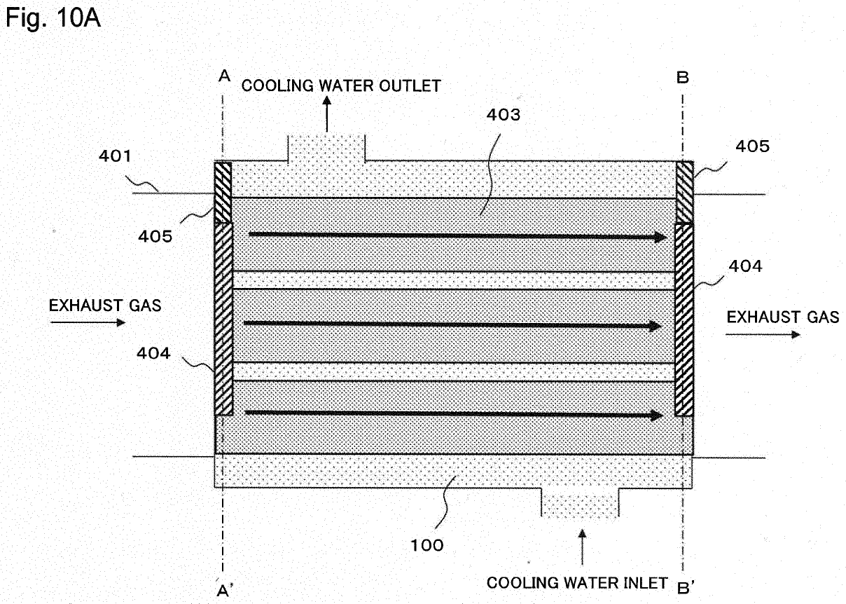

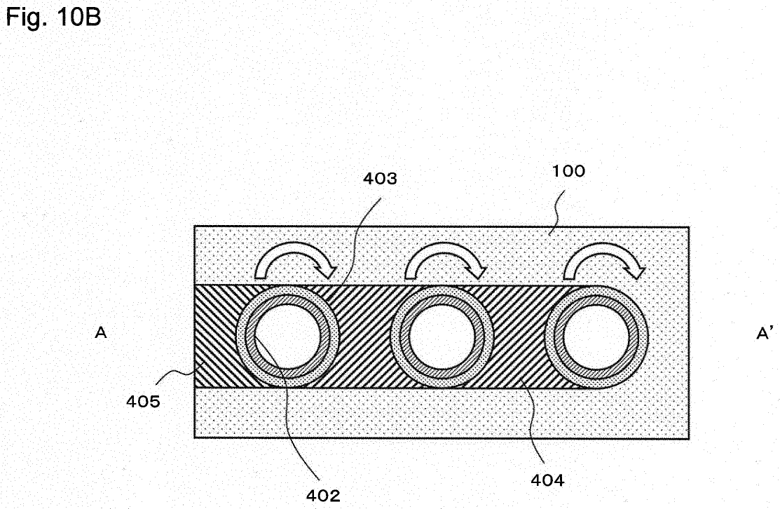

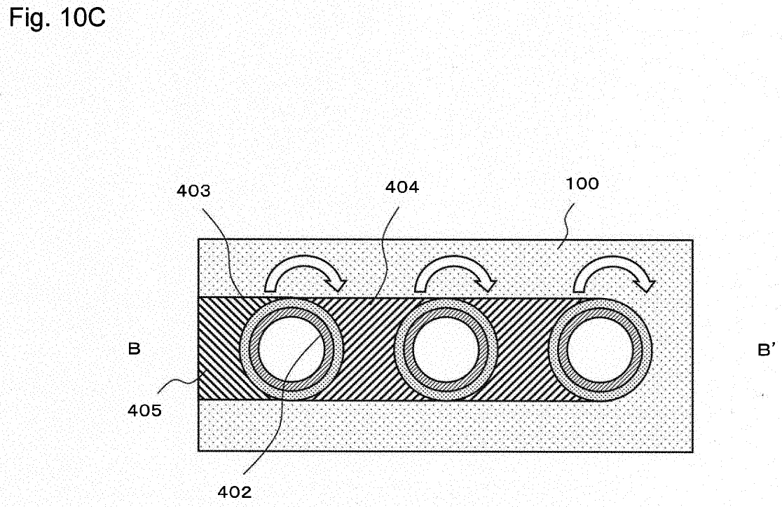

A fourth example embodiment according to the present invention is described in detail with reference to the drawings. FIG. 10A is a diagram illustrating an overview of a configuration of a power generation system of the present example embodiment. Further, FIGS. 10B and 10C are cross-sectional views of FIG. 10A. FIG. 10B is a cross-sectional view at a position along the line A-A′ in FIG. 10A. Further, FIG. 10C is a cross-sectional view at a position along the line B-B′ in FIG. 10A.

The power generation system of the present example embodiment includes a main exhaust gas pipe 401, a branch exhaust gas pipe 402, a sheet-shaped thermoelectric conversion element 403, an electric joint portion 404, and a terminal 405. A vicinity of the branch exhaust gas pipe 402 and each sheet-shaped thermoelectric conversion element is filled with circulating cooling water 100.

In the second example embodiment, a plurality of sheet-shaped thermoelectric conversion elements are connected to be electrically in series. However, the present example embodiment has a feature that each of the sheet-shaped thermoelectric conversion elements are connected in parallel to one another.

A configuration of the main exhaust gas pipe 401 and a configuration of the branch exhaust gas pipe 402 are respectively the same as those of a main exhaust gas pipe 201 and a branch exhaust gas pipe 202 in the second example embodiment.

Similarly to a sheet-shaped thermoelectric conversion element 203 in the second example embodiment, the sheet-shaped thermoelectric conversion element 403 is a thermoelectric conversion element in which current in an in-plane direction, specifically, in a plane direction is generated due to a temperature gradient in a direction perpendicular to a plane of a sheet.

A direction of current generated in the sheet-shaped thermoelectric conversion element 403 is determined by a magnetization direction of the sheet-shaped thermoelectric conversion element 403, and a sign of a spin Hall angle of material. Therefore, by magnetizing the sheet-shaped thermoelectric conversion element 403 in a circumferential direction of the branch exhaust gas pipe 402, current generated due to a temperature difference is generated in a longitudinal direction of the branch exhaust gas pipe 402. Further, since magnetization directions in a circumferential direction of the sheet-shaped thermoelectric conversion elements 403 are the same, directions of currents generated in the sheet-shaped thermoelectric conversion elements 403 become the same. The sheet-shaped thermoelectric conversion element 403 in the present example embodiment is formed as a thermoelectric conversion element using a spin Seebeck effect or an anomalous Nernst effect.

The electric joint portion 404 is mounted in such a way that each of the sheet-shaped thermoelectric conversion elements 403 are electrically connected in parallel to one another at an end of each of the sheet-shaped thermoelectric conversion elements 403. It is desirable that the electric joint portion 404 is made of material having a low electrical resistance. For example, the electric joint portion 404 is made of a metal such as Cu, Ag, Al, and Ti, or an alloy containing these elements. Generated current is extracted from the terminal 405 mounted on both ends of one of sheet-shaped thermoelectric conversion elements.

As illustrated in FIGS. 10B and 10C, when the branch exhaust gas pipes 402, around each of which the magnetized sheet-shaped thermoelectric conversion element 403 is wound, are bundled, magnetizations of the adjacent sheet-shaped thermoelectric conversion elements 403 interact with each other in such a way as to reinforce each other. Therefore, when magnetization stability of the sheet-shaped thermoelectric conversion element 403 is considered, it is desirable to set a distance between the branch exhaust gas pipes 402 to 10 centimeters or less. Further, in order to enhance magnetization stability of each sheet-shaped thermoelectric conversion element 403, a fluid having a high permeability as compared with water, for example, a magnetic fluid acquired by mixing ferromagnetic particles such as magnetite or manganese zinc ferrite in liquid, or an MR fluid, may be used as cooling water 100.

The main exhaust gas pipe 401 in FIGS. 10A, 10B, and 10C has a configuration such that the main exhaust gas pipe 401 is branched into three branch exhaust gas pipes 402, each of which has a circular cross section, and the branch exhaust gas pipes 402 are aligned one-dimensionally. A number of branch exhaust gas pipes 402 may be a number other than three. Further, as illustrated in FIG. 3, the branch exhaust gas pipes 402 may be configured to be bundled two-dimensionally. Furthermore, a cross-sectional structure of an exhaust gas pipe may not have a circular shape, but may have a square shape such as a quadrangular shape.

Since a temperature of exhaust gas differs between a vicinity of an exhaust gas inlet and a vicinity of an exhaust gas outlet, a distribution of material composition suitable for a temperature distribution may be formed in the sheet-shaped thermoelectric conversion element 403, similarly to the second example embodiment. For example, the vicinity of the exhaust gas inlet is formed by using material such that thermoelectric conversion efficiency in a temperature range of the vicinity of the exhaust gas inlet is higher than thermoelectric conversion efficiency in another temperature range, and a Curie temperature is higher than a temperature in the vicinity of the exhaust gas inlet. Further, the vicinity of the exhaust gas outlet is formed by using material such that thermoelectric conversion efficiency in a temperature range of the vicinity of the exhaust gas outlet is higher than thermoelectric conversion efficiency in another temperature range, and a Curie temperature is higher than a temperature in the vicinity of the exhaust gas outlet.

FIG. 10A illustrates a configuration that cooling water flows in an opposite direction. Alternatively, cooling water may flow in the same direction as a direction of exhaust gas. Further, cooling by air-cooling may be performed, in place of a cooling method employing cooling water. Furthermore, a fluid flowing through the main exhaust gas pipe 401 and the branch exhaust gas pipe 402 may be liquid.

### Manufacturing Method and Operation of Fourth Example Embodiment

A method for configuring the power generation system of the present example embodiment is described. The following description is made based on a premise that connection between the main exhaust gas pipe 401 and the branch exhaust gas pipe 402 is performed in advance. First, the sheet-shaped thermoelectric conversion element 403 is formed. Since the sheet-shaped thermoelectric conversion element 403 comes into contact with cooling water when being operated, a surface of the sheet-shaped thermoelectric conversion element 403 is required to be covered with a waterproof film.

After a magnetic film is formed, the sheet-shaped thermoelectric conversion element 403 is magnetized in an in-plane direction. The magnetized sheet-shaped thermoelectric conversion element 403 is wound around the branch exhaust gas pipe 402. When winding is performed, each of the sheet-shaped thermoelectric conversion elements 403 is wound in such a way that a magnetization direction is aligned with a circumferential shape of the branch exhaust gas pipe 402, and a magnetization direction in a circumferential direction becomes the same among the sheet-shaped thermoelectric conversion elements 403.

After winding is performed, the electric joint portion 404 is mounted on an end in such a way that the sheet-shaped thermoelectric conversion elements 403 are connected in parallel to one another. In view of a possibility that the electric joint portion 404 may come into contact with cooling water 100, the electric joint portion 404 is covered with a waterproof film. The terminal 405 is mounted on both ends of one of the sheet-shaped thermoelectric conversion elements.

An operation of the power generation system of the present example embodiment is described. In the power generation system of the present example embodiment, high-temperature gas flows through the main exhaust gas pipe 401. Gas flowing through the main exhaust gas pipe 401 is separated into each of the branch exhaust gas pipes 402 at a connecting portion between the main exhaust gas pipe 401 and each of the branch exhaust gas pipes 402, and flows through each branch exhaust gas pipe 402. Gas flowing through each branch exhaust gas pipe 402 merges at a connecting portion between each of the branch exhaust gas pipes 402 and the main exhaust gas pipe 401, and is discharged through the main exhaust gas pipe 401.

When gas flows through the branch exhaust gas pipe 402, a temperature difference occurs in a direction perpendicular to a plane of a sheet of the sheet-shaped thermoelectric conversion element 403 due to a temperature difference between gas and cooling water 100. A temperature difference in a direction perpendicular to a sheet generates current in the sheet-shaped thermoelectric conversion element 403 along a longitudinal direction of the branch exhaust gas pipe 402.

In the present example embodiment, the adjacent sheet-shaped thermoelectric conversion elements 403 are connected to each other by the electric joint portion 404, and current flows in the same direction in parallel with respect to a longitudinal direction of the branch exhaust gas pipe 402. Therefore, it is possible to acquire electric power by extracting current flowing through the parallel-connected sheet-shaped thermoelectric conversion elements 403, via the terminal 405.

### Advantageous Effects of Fourth Example Embodiment

The power generation system of the present example embodiment has advantageous effects similar to those of the second example embodiment. Specifically, the power generation system of the present example embodiment is able to efficiently perform power generation, based on thermal energy, while maintaining reliability without complicating a configuration. Further, in the power generation system of the present example embodiment, since current flows in the same direction with respect to the branch exhaust gas pipe among all sheet-shaped thermoelectric conversion elements, and the sheet-shaped thermoelectric conversion elements are electrically connected in parallel to one another, it is possible to increase current to be output.

### Fifth Example Embodiment

### Configuration of Fifth Example Embodiment

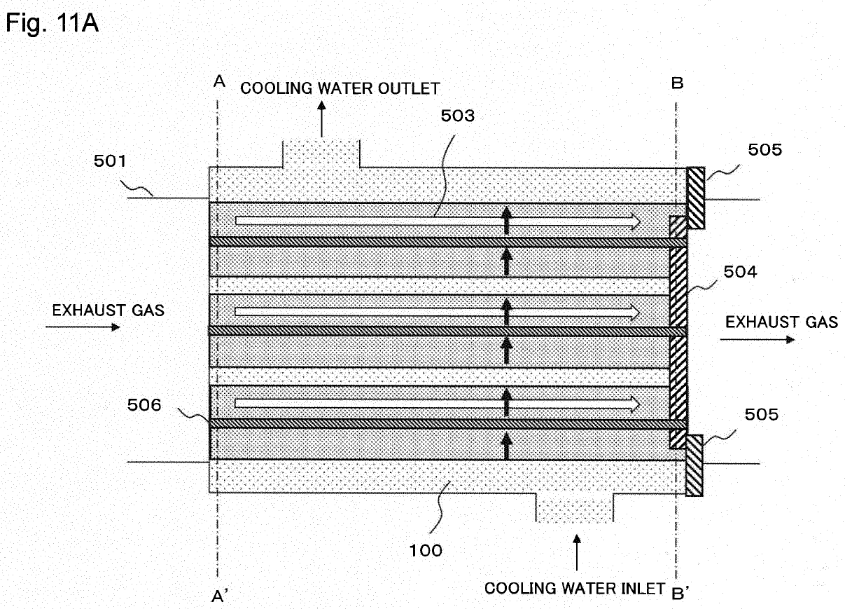

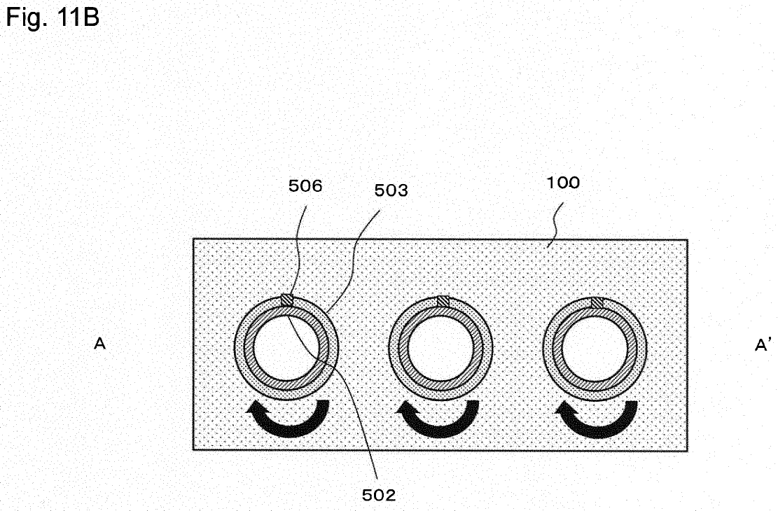

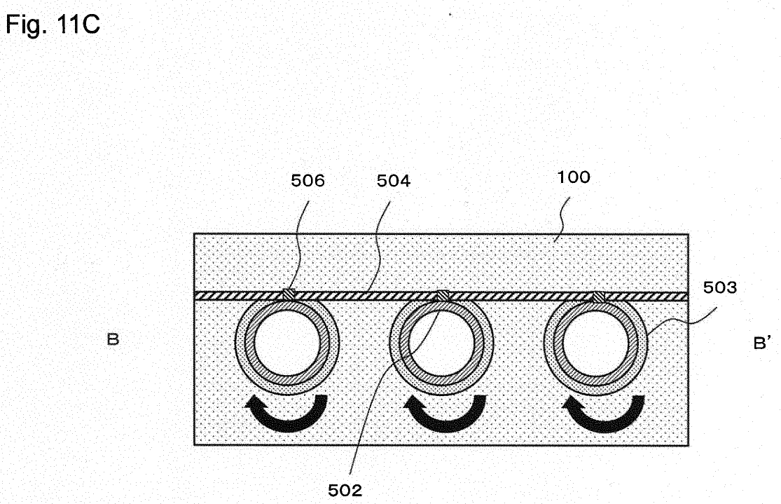

A fifth example embodiment according to the present invention is described in detail with reference to the drawings. FIG. 11A is a diagram illustrating an overview of a configuration of a power generation system of the present example embodiment. The power generation system of the present example embodiment includes a main exhaust gas pipe 501, a branch exhaust gas pipe 502, a sheet-shaped thermoelectric conversion element 503, an electric joint portion 504, a terminal 505, and an insulation portion 506. A vicinity of the branch exhaust gas pipe 502 and each sheet-shaped thermoelectric conversion element 503 is filled with circulating cooling water 100.

In the second example embodiment, current flowing in a longitudinal direction, specifically, in a gas flow direction through a branch exhaust gas pipe, is extracted. However, the power generation system of the present example embodiment has a feature that current flowing in a direction along a circumference of the branch exhaust gas pipe 502 is used.

A configuration of the main exhaust gas pipe 501 and a configuration of the branch exhaust gas pipe 502 are the same as those of a main exhaust gas pipe 201 and a branch exhaust gas pipe 202 in the second example embodiment.

The sheet-shaped thermoelectric conversion element 503 is magnetized in a longitudinal direction of the branch exhaust gas pipe 502, and current is generated in a circumferential direction of the branch exhaust gas pipe 502 due to a temperature difference in a direction perpendicular to a plane of a sheet. Further, magnetization directions in a longitudinal direction of each of the sheet-shaped thermoelectric conversion elements 503 are the same. Therefore, current generation directions in a circumferential direction are the same among the sheet-shaped thermoelectric conversion elements 503. As the sheet-shaped thermoelectric conversion element 503, a thermoelectric conversion element using a spin Seebeck effect or an anomalous Nernst effect is employed.

A part of each sheet-shaped thermoelectric conversion element 503 is insulated by the insulation portion 506. The electric joint portion 504 is mounted on an end in a longitudinal direction of each sheet-shaped thermoelectric conversion element 503 in such a way that the sheet-shaped thermoelectric conversion elements 503 are electrically connected in series. It is desirable that the electric joint portion 504 is made of material having a low electrical resistance. For example, the electric joint portion 504 is made of metal such as Cu, Ag, Al, and Ti, or an alloy containing these elements. Generated current is extracted via the terminal 505.

As illustrated in FIG. 11A, when the branch exhaust gas pipes 502, around each of which the magnetized sheet-shaped thermoelectric conversion element 503 is wound, are bundled, magnetizations of the adjacent sheet-shaped thermoelectric conversion elements 503 interact with each other in such a way as to cancel with each other. Therefore, when magnetization stability of the sheet-shaped thermoelectric conversion element 503 is considered, it is desirable to install each branch exhaust gas pipe 502 to be away from the adjacent branch exhaust gas pipe 502 by 10 micrometers or more.

FIGS. 11A, 11B, and 11C illustrate a configuration in which the branch exhaust gas pipe 502 is branched into three branch exhaust gas pipes 502, each of which has a circular cross section, and the branch exhaust gas pipes 502 are aligned one-dimensionally. A number of branch exhaust gas pipes 502 may be other than three. Further, the branch exhaust gas pipes 502 may be configured to be bundled two-dimensionally. Furthermore, a cross-sectional structure of an exhaust gas pipe may not have a circular shape, and may have a square shape such as a quadrangular shape.

Since a temperature of exhaust gas differs between a vicinity of an exhaust gas inlet and a vicinity of an exhaust gas outlet, a distribution of material composition suitable for a temperature distribution may be formed in the sheet-shaped thermoelectric conversion element 503, similarly to the second example embodiment. For example, the vicinity of the exhaust gas inlet is formed by using material such that thermoelectric conversion efficiency in a temperature range of the vicinity of the exhaust gas inlet is higher than thermoelectric conversion efficiency in another temperature range, and a Curie temperature is higher than a temperature in the vicinity of the exhaust gas inlet. Further, the vicinity of the exhaust gas outlet is formed by using material such that thermoelectric conversion efficiency in a temperature range of the vicinity of the exhaust gas outlet is higher than thermoelectric conversion efficiency in another temperature range, and a Curie temperature is higher than a temperature in the vicinity of the exhaust gas outlet.

FIG. 11A illustrates a configuration that cooling water 100 flows in an opposite direction. Alternatively, cooling water 100 may flow in the same direction as a direction of exhaust gas. Further, cooling by air-cooling may be performed, in place of a cooling method employing cooling water 100. Furthermore, high-temperature liquid may flow through the main exhaust gas pipe 501 and the branch exhaust gas pipe 502, in place of exhaust gas.

### Manufacturing Method and Operation of Fifth Example Embodiment

A method for configuring the power generation system of the present example embodiment is described. The following description is made based on a premise that connection between the main exhaust gas pipe 501 and the branch exhaust gas pipe 502 is performed in advance. First, the sheet-shaped thermoelectric conversion element 503 is formed.

The insulation portion 506 is formed on a part of each sheet-shaped thermoelectric conversion element 503. Since the sheet-shaped thermoelectric conversion element 503 comes into contact with cooling water 100 when being operated, a surface of the sheet-shaped thermoelectric conversion element 503 is required to be covered with a waterproof film.

After the insulation portion 506 is formed, magnetization of the sheet-shaped thermoelectric conversion element 503 in an in-plane direction is performed. After magnetization is performed, the magnetized sheet-shaped thermoelectric conversion element 503 is wound around the branch exhaust gas pipe 502. When winding is performed, each of the sheet-shaped thermoelectric conversion elements 503 is wound in such a way that a magnetization direction is aligned with a longitudinal direction of the branch exhaust gas pipe 502, and a magnetization direction becomes the same among the sheet-shaped thermoelectric conversion elements 503.

After winding is performed, the electric joint portion 504 is mounted on an end in such a way that the sheet-shaped thermoelectric conversion elements 503 are connected in series. Further, in view of a possibility that the electric joint portion 504 may come into contact with cooling water, the electric joint portion 504 is covered with a waterproof film.

After the electric joint portion 504 is mounted, the terminal 505 for extracting electric power is mounted on the sheet-shaped thermoelectric conversion elements 503 serving as both ends when the sheet-shaped thermoelectric conversion elements 503 are connected in series, and the terminal 505 is connected to a circuit serving as a supply target of electric power.

An operation of the power generation system of the present example embodiment is described. In the power generation system of the present example embodiment, high-temperature gas flows through the main exhaust gas pipe 501. Gas flowing through the main exhaust gas pipe 501 is separated into each of the branch exhaust gas pipes 502 at a connecting portion between the main exhaust gas pipe 501 and each of the branch exhaust gas pipes 502, and flows through each branch exhaust gas pipe 502. Gas flowing through each branch exhaust gas pipe 502 merges at a connecting portion between each of the branch exhaust gas pipes 502 and the main exhaust gas pipe 501, and is discharged through the main exhaust gas pipe 501.

When gas flows through the branch exhaust gas pipe 502, a temperature difference occurs in a direction perpendicular to a plane of a sheet of the sheet-shaped thermoelectric conversion element 503 due to a temperature difference between gas and cooling water 100. A temperature difference in a direction perpendicular to a sheet generates current in the sheet-shaped thermoelectric conversion element 503 along a circumferential direction of the branch exhaust gas pipe 502.

In the present example embodiment, the adjacent sheet-shaped thermoelectric conversion elements 503 are connected to each other by the electric joint portion 504, and current flows in the same direction with respect to a circumferential direction of the branch exhaust gas pipe 502 among the sheet-shaped thermoelectric conversion elements 503. Therefore, it is possible to acquire electric power by extracting current flowing through the sheet-shaped thermoelectric conversion element 503 via the terminals 505, which are formed on the sheet-shaped thermoelectric conversion elements 503 at both ends.

### Advantageous Effects of Fifth Example Embodiment

The power generation system of the present example embodiment has advantageous effects similar to those of the second example embodiment. Specifically, the power generation system of the present example embodiment is able to efficiently perform power generation, based on thermal energy, while maintaining reliability without complicating a configuration. Further, in the power generation system of the present example embodiment, since current flows in the same circumferential direction with respect to the branch exhaust gas pipe among all sheet-shaped thermoelectric conversion elements, and a size of direction in a direction perpendicular to a current flow direction is longer. Therefore, reliability improves, since the sheet-shaped thermoelectric conversion element is less likely to be affected, even when breakage occurs in a part of the sheet-shaped thermoelectric conversion element.

The first to fifth example embodiments describe an example of a linear-shaped branch exhaust gas pipe. Alternatively, an entirety or a part of a branch exhaust gas pipe may be curved shape. Further, the second to fifth example embodiments describe an example in which each of a number of cooling water inlets and a number of cooling water outlets is one. Alternatively, each of a number of cooling water inlets and a number of cooling water outlets may be plural. Further, when a plurality of cooling water inlets and a plurality of cooling water outlets are disposed, a flow path of cooling water within a thermoelectric conversion unit may be partitioned into a plurality of sections. Further, the second to fifth example embodiments describe a configuration in which there is only one thermoelectric conversion unit. Alternatively, a plurality of thermoelectric conversion units may be formed.

A configuration of a power generation system of each of the second to fifth example embodiments may be applied to a multi-stage cooling system. When such a configuration is made, for example, a first fluid flowing through a main exhaust gas pipe is separated into branch exhaust gas pipes, and first-time power generation is performed by a sheet-shaped thermoelectric conversion element, based on a temperature difference when cooling is performed by a second fluid whose temperature is lower than the first fluid. Then, the second fluid is guided to another thermoelectric conversion unit, and second-time power generation is performed by the sheet-shaped thermoelectric conversion element, based on a temperature difference when cooling is performed by a third fluid whose temperature is further lower than the second fluid. In this way, performing multi-stage cooling and power generation enables to more efficiently use thermal energy. Further, when multi-stage power generation is performed, it is possible to more efficiently perform power generation by employing a thermoelectric conversion element made of material having high thermoelectric conversion efficiency at a temperature of each fluid. In such a case, a sheet-shaped thermoelectric conversion element having high thermoelectric conversion efficiency on a low-temperature side, as compared with a thermoelectric conversion element of a thermoelectric conversion unit which performs first-stage cooling, is employed as a thermoelectric conversion element of a thermoelectric conversion unit which performs second-stage cooling. Further, a cooling and power generation system may have three or more stages.

A power generation system of each of the second to fifth example embodiments generates electric power by a sheet-shaped thermoelectric conversion element, based on a temperature difference when a high-temperature fluid is cooled by a low-temperature fluid. Alternatively, power generation may be performed due to a temperature difference when a low-temperature fluid is heated at a high temperature. When such a configuration is made, a low-temperature fluid is introduced to a main exhaust gas pipe and a branch exhaust gas pipe.

The whole or part of the example embodiments disclosed above can be described as, but not limited to, the following supplementary notes.

### Supplementary Note 1

A thermoelectric conversion unit including:

a plurality of pipes through which a first fluid flows; and

a sheet-shaped thermoelectric conversion element being wound around each of the pipes, and configured to generate electric power, based on a temperature difference between the first fluid and a second fluid flowing outside the pipe.

### Supplementary Note 2

The thermoelectric conversion unit according to supplementary note 1, wherein

the thermoelectric conversion element is configured in such a way that current flows in a direction along a circumference of the pipe orthogonal to a magnetization direction or in a longitudinal direction, due to the temperature difference between the first fluid and the second fluid.

### Supplementary Note 3

The thermoelectric conversion unit according to supplementary note 1 or 2, wherein

the thermoelectric conversion element uses a spin Seebeck effect or an anomalous Nernst effect.

### Supplementary Note 4

The thermoelectric conversion unit according to any one of supplementary notes 1 to 3, wherein

the second fluid flows in a vicinity of the pipe in such a way as to oppose a flow of the first fluid.

### Supplementary Note 5

The thermoelectric conversion unit according to any one of supplementary notes 1 to 3, further including:

a branching portion being formed on an inlet side of the first fluid, and configured to branch a main pipe into the plurality of the pipes; and

a connecting portion being formed on an outlet side of the first fluid, and configured to connect the plurality of the pipes and the main pipe, wherein

the plurality of the pipes are formed to be in parallel with one another, and

the thermoelectric conversion unit is wound around the pipe in such a way as to continue on a substantially entire portion between the branching portion and the connecting portion.

### Supplementary Note 6

The thermoelectric conversion unit according to any one of supplementary notes 1 to 5, wherein

the thermoelectric conversion element has a gradient in a composition distribution of material in a longitudinal direction of the pipe.

### Supplementary Note 7

The thermoelectric conversion unit according to supplementary note 6, wherein

the thermoelectric conversion element has material composition in which thermoelectric conversion efficiency is high in a high temperature region on an inlet side of the first fluid, as compared with an outlet side, and has material composition in which thermoelectric conversion efficiency is high in a low temperature region on an outlet side of the first fluid, as compared with the inlet side.

### Supplementary Note 8

The thermoelectric conversion unit according to any one of supplementary notes 1 to 7, wherein

the thermoelectric conversion element is wound around each of the pipes in such a way that a direction of generated current becomes alternate between the adjacent thermoelectric conversion elements, and

the thermoelectric conversion elements are connected in such a way that current flows in series.

### Supplementary Note 9

The thermoelectric conversion unit according to supplementary note 8, wherein

current generated in the adjacent thermoelectric conversion elements flows in directions opposite to each other by making magnetization directions of the adjacent thermoelectric conversion elements different from each other.

### Supplementary Note 10

The thermoelectric conversion unit according to supplementary note 8, wherein

current generated in the adjacent thermoelectric conversion elements flows in directions opposite to each other by making signs of spin Hall angles of the adjacent thermoelectric conversion elements different from each other.

### Supplementary Note 11

The thermoelectric conversion unit according to any one of supplementary notes 8 to 10, wherein

the thermoelectric conversion elements wound around the adjacent pipes are away from each other by 10 micrometers or more.

### Supplementary Note 12

The thermoelectric conversion unit according to any one of supplementary notes 1 to 7, wherein

the thermoelectric conversion element is wound around each of a plurality of the pipes in such a way that a direction of generated current becomes the same, and the thermoelectric conversion elements wound around a plurality of the pipes are connected in such a way that current flows in parallel.

### Supplementary Note 13

The thermoelectric conversion unit according to supplementary note 12, wherein

the thermoelectric conversion elements wound around the adjacent pipes are away from each other by 10 centimeters or less.

### Supplementary Note 14

The thermoelectric conversion unit according to any one of supplementary notes 1 to 7, wherein

current flows in the thermoelectric conversion element along a circumferential direction of the pipe, and

the thermoelectric conversion element further includes an insulation portion on a part of the circumferential direction.

### Supplementary Note 15

The thermoelectric conversion unit according to any one of supplementary notes 1 to 14, wherein

the second fluid is a fluid having a high permeability as compared with water.

### Supplementary Note 16

A power generation system including:

a main pipe through which a first fluid flows;

the thermoelectric conversion unit according to any one of supplementary notes 1 to 15; and

a terminal portion for extracting electric power generated in the thermoelectric conversion element, wherein

the pipe of the thermoelectric conversion unit is a pipe branched from the main pipe, and

the terminal portion outputs current generated in the thermoelectric conversion element due to a temperature difference between the first fluid flowing from the main pipe into the pipe, and the second fluid.

### Supplementary Note 17

A thermoelectric conversion method including:

flowing a first fluid through a plurality of pipes; and

generating electric power by a sheet-shaped thermoelectric conversion element wound around each of the pipes, based on a temperature difference between the first fluid and a second fluid flowing outside the pipe.

### Supplementary Note 18

The thermoelectric conversion method according to supplementary note 17, further including:

generating current by the thermoelectric conversion element in a direction along a circumference of the pipe or in a length direction, due to the temperature difference between the first fluid and the second fluid.

### Supplementary Note 19

The thermoelectric conversion method according to supplementary note 17 or 18, further including:

flowing the second fluid in a vicinity of the pipe in such a way as to oppose a flow of the first fluid.

### Supplementary Note 20

The thermoelectric conversion method according to any one of supplementary notes 17 to 19, further including:

branching a main pipe into the plurality of the pipes on an inlet side of the first fluid;

disposing the plurality of the pipes in parallel with one another;

winding the thermoelectric conversion element around the pipe in such a way as to continue on a substantially entire portion between the branching portion and the connecting portion; and

connecting the plurality of the pipes and the main pipe on an outlet side of the first fluid.

### Supplementary Note 21

The thermoelectric conversion method according to any one of supplementary notes 17 to 20, wherein

the thermoelectric conversion element has a gradient in a composition distribution of material in a longitudinal direction of the pipe.

### Supplementary Note 22

The thermoelectric conversion method according to supplementary note 21, wherein

the thermoelectric conversion element has material composition in which thermoelectric conversion efficiency is high in a high temperature region on an inlet side of the first fluid, as compared with an outlet side, and has material composition in which thermoelectric conversion efficiency is high in a low temperature region on an outlet side of the first fluid, as compared with the inlet side.

### Supplementary Note 23

The thermoelectric conversion method according to any one of supplementary notes 17 to 22, further including:

winding the thermoelectric conversion element around each of the pipes in such a way that a direction of generated current becomes alternate between the adjacent thermoelectric conversion elements; and
connecting the thermoelectric conversion elements in such a way that current flows in series.

### Supplementary Note 24

The thermoelectric conversion method according to supplementary note 23, further including:

flowing current generated in the adjacent thermoelectric conversion elements in directions opposite to each other by making magnetization directions of the adjacent thermoelectric conversion elements different from each other.

### Supplementary Note 25

The thermoelectric conversion method according to supplementary note 23, further including:

flowing current generated in the adjacent thermoelectric conversion elements in directions opposite to each other by making signs of spin Hall angles of the adjacent thermoelectric conversion elements different from each other.

### Supplementary Note 26

The thermoelectric conversion method according to any one of supplementary notes 17 to 22, further including:

winding the thermoelectric conversion element around each of the plurality of the pipes in such a way that a direction of generated current becomes the same; and

connecting the thermoelectric conversion elements wound around a plurality of the pipes in such a way that current flows in parallel.

### Supplementary Note 27

The thermoelectric conversion method according to any one of supplementary notes 17 to 22, further including:

forming the thermoelectric conversion element in such a way that current flows along a circumferential direction of the pipe; and insulating a part of the circumferential direction.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2016-238405, filed on Dec. 8, 2016, the disclosure of which is incorporated herein in its entirety by reference.

### REFERENCE SIGNS LIST

1 Pipe
2 Thermoelectric conversion element
13 Exhaust passage
13A Exhaust passage
13B Exhaust passage
13C Exhaust passage
14 Recess portion
15 Thermoelectric conversion element
31 Branch exhaust gas pipe
32 Sheet-shaped thermoelectric conversion element
100 Cooling water
201 Main exhaust gas pipe
202 Branch exhaust gas pipe
203 Sheet-shaped thermoelectric conversion element
204 Electric joint portion
205 Terminal
301 Main exhaust gas pipe
302 Branch exhaust gas pipe
303A First sheet-shaped thermoelectric conversion element
303B Second sheet-shaped thermoelectric conversion element
304 Electric joint portion
305 Terminal
401 Main exhaust gas pipe
402 Branch exhaust gas pipe
403 Sheet-shaped thermoelectric conversion element
404 Electric joint portion
405 Terminal
501 Main exhaust gas pipe
502 Branch exhaust gas pipe
503 Sheet-shaped thermoelectric conversion element
504 Electric joint portion
505 Terminal
506 Insulation portion
601 Main exhaust gas pipe
602 Branch exhaust gas pipe
603 Sheet-shaped anomalous Nernst thermoelectric conversion element
604 Electric joint portion
605 Terminal
606 Electric joint portion
701 Substrate
702 Magnetic film
801 Main exhaust gas pipe
802 Branch exhaust gas pipe
803A Sheet-shaped spin Seebeck thermoelectric conversion element
803B Sheet-shaped spin Seebeck thermoelectric conversion element
804 Electric joint portion
805 Terminal
901 Substrate
902 Magnetic insulation film
903A Metal film
903B Metal film

1. A thermoelectric conversion unit comprising:
a plurality of pipes through which a first fluid flows; and
a sheet-shaped thermoelectric conversion element being wound around each of the pipes, and configured to generate electric power, based on a temperature difference between the first fluid and a second fluid flowing outside the pipe.

2. The thermoelectric conversion unit according to claim 1, wherein
the thermoelectric conversion element is configured in such a way that current flows in a direction along a circumference of the pipe orthogonal to a magnetization direction or in a longitudinal direction, due to the temperature difference between the first fluid and the second fluid.

3. The thermoelectric conversion unit according to claim 1, wherein
the thermoelectric conversion element uses a spin Seebeck effect or an anomalous Nernst effect.

4. The thermoelectric conversion unit according to claim 1, wherein
the second fluid flows in a vicinity of the pipe in such a way as to oppose a flow of the first fluid.

5. The thermoelectric conversion unit according to claim 1, further comprising:
a branching portion being formed on an inlet side of the first fluid, and configured to branch a main pipe into the plurality of the pipes; and
a connecting portion being formed on an outlet side of the first fluid, and configured to connect the plurality of the pipes and the main pipe, wherein
the plurality of the pipes are formed to be in parallel with one another, and
the thermoelectric conversion unit is wound around the pipe in such a way as to continue on a substantially entire portion between the branching portion and the connecting portion.

6. The thermoelectric conversion unit according to claim 1, wherein
the thermoelectric conversion element has a gradient in a composition distribution of material in a longitudinal direction of the pipe.

7. The thermoelectric conversion unit according to claim 6, wherein
the thermoelectric conversion element has material composition in which thermoelectric conversion efficiency is high in a high temperature region on an inlet side of the first fluid, as compared with an outlet side, and has material composition in which thermoelectric conversion efficiency is high in a low temperature region on an outlet side of the first fluid, as compared with the inlet side.

8. The thermoelectric conversion unit according to claim 1, wherein
the thermoelectric conversion element is wound around each of the pipes in such a way that a direction of generated current becomes alternate between the adjacent thermoelectric conversion elements, and
the thermoelectric conversion elements are connected in such a way that current flows in series.

9. The thermoelectric conversion unit according to claim 8, wherein
current generated in the adjacent thermoelectric conversion elements flows in directions opposite to each other by making magnetization directions of the adjacent thermoelectric conversion elements different from each other.

10. The thermoelectric conversion unit according to claim 8, wherein
current generated in the adjacent thermoelectric conversion elements flows in directions opposite to each other by making signs of spin Hall angles of the adjacent thermoelectric conversion elements different from each other.

11. (canceled)

12. The thermoelectric conversion unit according to claim 1, wherein
the thermoelectric conversion element is wound around each of the plurality of the pipes in such a way that a direction of generated current becomes the same, and the thermoelectric conversion elements wound around the plurality of the pipes are connected in such a way that current flows in parallel.

13. (canceled)

14. The thermoelectric conversion unit according to claim 1, wherein
current flows in the thermoelectric conversion element along a circumferential direction of the pipe, and
the thermoelectric conversion element further includes an insulation portion on a part of the circumferential direction.

15. The thermoelectric conversion unit according to claim 1, wherein
the second fluid is a fluid having a high permeability as compared with water.

16. A power generation system comprising:
a main pipe through which a first fluid flows;
the thermoelectric conversion unit according to claim 1; and
a terminal portion for extracting electric power generated in the thermoelectric conversion element, wherein
the pipe of the thermoelectric conversion unit is a pipe branched from the main pipe, and
the terminal portion outputs current generated in the thermoelectric conversion element due to a temperature difference between the first fluid flowing from the main pipe into the pipe, and the second fluid.

17. A thermoelectric conversion method comprising:
flowing a first fluid through a plurality of pipes; and
generating electric power by a sheet-shaped thermoelectric conversion element wound around each of the pipes, based on a temperature difference between the first fluid and a second fluid flowing outside the pipe.

18. The thermoelectric conversion method according to claim 17, further comprising:
generating current by the thermoelectric conversion element in a direction along a circumference of the pipe or in a length direction, due to the temperature difference between the first fluid and the second fluid.

19. The thermoelectric conversion method according to claim 17, further comprising:
flowing the second fluid in a vicinity of the pipe in such a way as to oppose a flow of the first fluid.

20. The thermoelectric conversion method according to claim 17, further comprising:
branching a main pipe into the plurality of the pipes at a branching portion on an inlet side of the first fluid;
making the plurality of the pipes in parallel with one another;
connecting the plurality of the pipes and the main pipe at a connecting portion on an outlet side of the first fluid;
winding the thermoelectric conversion element around the pipe in such a way as to continue on a substantially entire portion between the branching portion and the connecting portion; and
connecting the plurality of the pipes and the main pipe on an outlet side of the first fluid.

21. The thermoelectric conversion method according to claim 17, wherein
the thermoelectric conversion element has a gradient in a composition distribution of material in a longitudinal direction of the pipe.

22. The thermoelectric conversion method according to claim 21, wherein
the thermoelectric conversion element has material composition in which thermoelectric conversion efficiency is high in a high temperature region on an inlet side of the first fluid, as compared with an outlet side, and has material composition in which thermoelectric conversion efficiency is high in a low temperature region on an outlet side of the first fluid, as compared with the inlet side.

23. (canceled)

24. (canceled)

25. (canceled)

26. (canceled)

27. (canceled)
